(19) United States
(12) Patent Application Publication
(10) Pub. No.: US 2010/0239782 A1
(43) Pub. Date: Sep. 23, 2010

(54) INSULATING FILM FORMING METHOD, INSULATING FILM FORMING APPARATUS, AND PLASMA FILM FORMING APPARATUS

(75) Inventors: Atsushi SASAKI, Yokohama-shi (JP); Kazufumi Azuma, Yokohama-shi (JP); Tetsuya Ide, Yokohama-shi (JP); Yukihiko Nakata, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Advanced LCD Technologies Dev. Ctr., Co., Ltd, Yokohama-shi (JP)

(21) Appl. No.: 12/792,226

(22) Filed: Jun. 2, 2010

Related U.S. Application Data
(62) Division of application No. 11/081,035, filed on Mar. 16, 2005.

(30) Foreign Application Priority Data
Mar. 19, 2004 (JP) 2004-081307
Mar. 26, 2004 (JP) 2004-093199
Jun. 29, 2004 (JP) 2004-191804

(51) Int. Cl. C23C 16/513

(52) U.S. Cl. 427/575

(57) ABSTRACT

An insulating film is formed with a plasma film forming apparatus which includes a vacuum vessel with an electromagnetic wave incident face F, first gas injection holes made in the vacuum vessel, and second gas injection holes made in the vacuum vessel farther away from the electromagnetic wave incident face F than the first gas injection holes. For example, a first gas is introduced from a position whose distance from the electromagnetic wave incident face F is less than 10 mm into the vacuum vessel. A second gas including an organic silicon compound is introduced from a position whose distance from the electromagnetic wave incident face is 10 mm or more into the vacuum vessel.

### CROSS-REFERENCE TO RELATED APPLICATIONS

This application is based upon and claims the benefit of priority from prior Japanese Patent Applications No. 2004-081307, filed Mar. 19, 2004; No. 2004-093199, filed Mar. 26, 2004 and No. 2004-191804, filed Jun. 29, 2004, the entire contents of all of which are incorporated herein by reference.

### BACKGROUND OF THE INVENTION

1. Field of the Invention

This invention relates to an insulating film forming method and an insulating film forming apparatus and a plasma film-forming apparatus which are suitable for forming an insulating film in the manufacturing process of semiconductor elements, such as thin-film transistors (TFTs) or metal-oxide semiconductor conductors (MOS elements), semiconductor devices, such as semiconductor integrated circuit devices, or display devices, such as liquid-crystal display devices, and in the manufacturing process of thin-film transistors.

2. Description of the Related Art

In the process of manufacturing semiconductor devices or liquid-crystal display devices, one known method is to form an insulating film on a substrate with a parallel-plate type high-frequency plasma enhanced chemical vapor deposition unit using an organic silicon compound as a process gas.

The parallel-plate type high-frequency plasma enhanced chemical vapor deposition unit includes a vacuum chamber, a high-frequency power supply, a high-frequency electrode, and an earth electrode. The vacuum chamber has a gas introducing portion which introduces a mixed gas of organic silicon compound gas and oxygen.

With the parallel-plate type high-frequency plasma enhanced chemical vapor deposition unit, an insulating film is formed as follows. Organic silicon compound gas and oxygen gas are introduced via the gas introducing portion into the vacuum chamber. The high-frequency power supply supplies a 13.56-MHz high-frequency power to the high-frequency electrode, thereby producing plasma in the vacuum chamber. Then, the organic silicon compound is decomposed by the plasma, with the result that a silicon oxide film made from the organic silicon compound is formed on a substrate (refer to, for example, Jpn. Pat. Appln. KOKAI Publication No. 5-345831).

However, the parallel-plate type high-frequency plasma enhanced chemical vapor deposition unit has the following problem: since plasma produced in the vacuum chamber spreads as far as the region where the substrate to be processed is provided, the surface of the substrate and the interface between the substrate and the insulating film are liable to suffer ion damage. Specifically, when plasma spreads as far as the region where the substrate is provided, the substrate comes into contact with high-energy electrons, with the result that a sheath electric field tending to increase according to the energy of electrons becomes larger. As the sheath electric field becomes larger, the energy of ions entering the substrate increases accordingly, with the result that the surface of the substrate and the interface between the substrate and the insulating film are liable to suffer ion damage.

To overcome this problem, the following methods have been proposed in recent years in the manufacturing process of semiconductor devices or liquid-crystal devices: a method of performing a plasma process in a localized plasma state using a plasma process unit which produces surface-wave plasma (or a plasma process method) and a method of forming an insulating film on a substrate using an insulating film forming unit (refer to, for example, Jpn. Pat. Appln. KOKAI Publication No. 2002-299241). Silane gas (such as monosilane gas) is generally used as the process gas.

To realize the plasma process method, a plasma process unit has been proposed which includes a process chamber, a dielectric barrier (dielectric plate), a plasma excitation gas shower plate, a process gas shower plate, a radial line slot antenna, and a magnetron which produces 2.45-GHz microwaves. The dielectric barrier is provided below the radial line slot antennal. The plasma excitation gas shower plate is provided below the dielectric barrier. The process gas shower plate is provided below the plasma gas shower plate.

The plasma process method using the plasma process unit is carried out as explained below. Rare gas as plasma excitation gas is introduced into the process chamber via a plurality of openings made in the plasma excitation gas shower plate. The microwave radiated from the radial line slot antenna is caused to enter the process chamber. As a result, the rare gas is excited, producing plasma in the chamber. The process gas is introduced into the process chamber via a plurality of openings made in the process gas shower plate. As a result, the process gas reacts with the plasma, performing a plasma process on the substrate to be processed.

One known insulating film forming apparatus includes a vacuum chamber, a dielectric barrier (dielectric plate), a radial line slot antennal, and a microwave generator which generate 8.3-GHz microwaves. The vacuum chamber has a first gas introducing portion which introduces a mixed gas of krypton gas and oxygen gas and a second gas introducing portion which introduces silane gas. The dielectric barrier constitutes a part of the vacuum chamber. The radial line slot antenna is provided along the dielectric barrier. The first gas introducing portion is provided closer to the radial line slot antenna than the second gas introducing portion. The position of the second gas introducing portion is set so as to take in silane gas from a region where the electron temperature is equal to or lower than 1 eV.

When an insulating film is formed using the insulating film forming apparatus, it proceeds as follows. A mixed gas of krypton gas and oxygen gas is introduced into the vacuum chamber via the first gas introducing portion. The electromagnetic wave radiated from the radial slot antenna is transmitted via the dielectric barrier (dielectric plate) to the vacuum chamber. As a result, the oxygen and krypton are excited, producing surface-wave plasma in the vacuum chamber. The surface-wave plasma produces oxygen radicals. Silane gas is introduced from the second gas introducing portion. The oxygen radicals are caused to decompose and react with the silane gas, which forms a silicon oxide film as an insulating film on the substrate (refer to, for example, Hiroki Tanaka, et al., “High-Quality Silicon Oxide Film Formed by Diffusion Region Plasma Enhanced Chemical Vapor Deposition and Oxygen Radical Treatment Using Microwave-Excited High-Density Plasma,” Jpn. J. Appl. Phys. Vol. 42 (2003), pp. 1911-1915).

Another known insulating film forming apparatus includes a process chamber, a dielectric barrier, a plasma excitation gas shower plate, a process gas shower plate, a radial line slot antenna, and a magnetron which generates 2.45-GHz microwaves. The dielectric barrier is provided below the radial line slot antenna. The plasma excitation gas shower plate is provided below the dielectric barrier. The process gas shower plate is provided below the plasma excitation gas shower plate.

The insulating film forming apparatus is used as follows. Rare gas as plasma excitation gas is introduced into the process chamber via a plurality of openings made in the plasma excitation gas shower plate. The microwave radiated from the radial line slot antenna is introduced into the process chamber via the plasma excitation gas shower plate. As a result, the rare gas is excited, thereby producing plasma. Process gas is supplied via a plurality of openings made in the process gas shower plate. As a result, the process gas reacts with the plasma, which performs a specific process on the substrate to be processed (refer to, for example, Jpn. Pat. Appln. KOKAI Publication No. 2002-299241).

Since metal oxide, such as hafnium oxide or zirconium oxide, has higher permittivity than silicon oxide, it has gotten a lot of attention as a material for insulating films. Known methods of forming a film made of metal oxide, such as hafnium oxide or zirconium oxide (hereinafter, referred to as a metal oxide film) include metalorganic chemical vapor deposition (MOCVD), sputtering, and atom layer deposition (ALD).

However, in metalorganic chemical vapor deposition, since organic metallic compound gas as a material is decomposed by the substrate heated to 500 degree C. to 700 degree C. to grow a film, it is difficult to apply the method to a substrate to be processed whose melting point is relatively low as a glass substrate or a plastic substrate. In sputtering, since high-speed neutral particles bounced from the target collide with the substrate to be processed, the substrate is liable to be damaged. In atom layer deposition, since atom layers are deposited one by one, the film forming speed is very low.

To overcome these problems, a method of forming a zirconium oxide film using plasma has been proposed in recent years. First, a mixed gas of tetra-propoxy zirconium (Zr(OC₃H₇)₄) gas, oxygen gas, and argon gas is prepared. At this time, the ratio of oxygen gas to argon gas in the mixed gas is set to 1:5. The mixed gas is introduced into the chamber in which a substrate to be processed has been provided. Plasma is produced in the chamber, thereby causing the Zr(OC₃H₇)₄ gas to plasma-discharge, which forms a zirconium oxide film on the substrate (refer to, for example, Reiji Morioka, et al., “Deposition of High-k Zirconium Oxides in VHF Plasma-Enhanced CVD Using Metal-Organic Precursor,” Extended Abstracts of The 20th Symposium on Plasma Processing (SPP-20), Jan. 29, 2003, pp. 317-318, hosted by a Division of Plasma Electronics of Japan Society of Applied physics).

Furthermore, one known method of forming a gate insulating film on a semiconductor layer in the manufacturing process of semiconductor devices or liquid-crystal display devices is to oxidize the surface of a semiconductor layer in an atmosphere including oxygen atom active species, thereby forming a first insulating film (oxide film), and then form a second insulating film (CVD film) on the first insulating film by plasma CVD techniques. In addition, another known method is to sequentially form a second insulating film on the first insulating film without exposing the first insulating film to air after the formation of the first insulating film. When such a gate insulating film is formed, a manufacturing apparatus as described below is used.

The manufacturing apparatus comprises a first reaction chamber for forming a first insulating film and a second reaction chamber for forming a second insulating film on the first insulating film without exposing the first insulating film to air. The first reaction chamber has a xenon excimer lamp. In the first reaction chamber, the surface of a semiconductor layer is oxidized in an atmosphere including oxygen atom active species produced by the light from the xenon excimer lamp, thereby forming a first insulating film. The second reaction chamber is a parallel-plate type plasma CVD film forming chamber which includes an anode electrode and a cathode electrode. In the second reaction chamber, a second insulating film made of silicon oxide is formed by plasma CVD using silane gas and dinitrogen monoxide gas (refer to, for example, Jpn. Pat. Appln. KOKAI Publication No. 2002-208592).

Use of organic silicon compound gas as the process gas makes it easier to obtain a silicon oxide film with good coating properties than use of silane gas. The reason for this is that the organic silicon compound has a larger molecular volume than silane. Therefore, the intermediate product obtained by decomposing the organic silicon compound by plasma has a relatively large molecular volume. With its three-dimensional effect, the intermediate product adheres to the surface of the substrate in a relatively uniform manner, while migrating over the substrate. Consequently, a silicon oxide film with good coating properties is obtained.

However, since the organic silicon compound has alkyl groups or the like in its skeleton, when the organic silicon compound is decomposed excessively, the carbon atoms included in the carbon skeleton are liable to get mixed into the formed silicon oxide in the form of impurities. That is, the excessive decomposition has a more harmful effect than silane gas used in the technique described in the document by Hiroki Tanaka, et al.

In the technique described in the document by Reiji Morioka, et al., since the partial pressure of oxygen gas in the mixed gas is kept low, oxygen deficiency in the metal oxide film formed is liable to occur.

In the plasma process method disclosed in Jpn. Pat. Appln. KOKAI Publication No. 2002-299241, it is difficult to form an insulating film of good film thickness uniformity. Specifically, in the plasma process method disclosed in Jpn. Pat. Appln. KOKAI Publication No. 2002-299241, a plasma process apparatus provided with a lattice-like process gas shower plate is used. However, such a plasma process apparatus has the following problem: it is difficult to form a film uniformly on the surface to be processed whose area is larger than a square several tens of centimeters each side, such as a liquid-crystal display. That is, when an insulating film is formed on a substrate with a large area, there are irregularities in the amount of process gas supplied. As a result, on the surface to be processed of the substrate corresponding to the region to which more process gas is supplied, an insulating film to be formed is liable to become thicker.

In the technique disclosed in Jpn. Pat. Appln. KOKAI Publication No. 2002-208592, a photooxidation film is formed as a first insulating film on a semiconductor layer with an optical processing apparatus and then a CVD film is formed as a second insulating film on the photooxidation film with a parallel-plate type plasma CVD apparatus. However, in the process of forming a CVD film on the photooxidation film with the parallel-plate type plasma CVD apparatus, the following problem arises: the photooxidation film and semiconductor layer are liable to be damaged.

Specifically, in the parallel-plate type plasma CVD apparatus, plasma produced in the second reaction chamber spreads as far as the region where the semiconductor layer is provided. When the plasma has spread as far as the region where the semiconductor layer has been provided, the photooxidation film and semiconductor layer come into contact with high-energy electrons, with the result that a sheath electric field tending to increase according to the energy of electrons grows larger. As the sheath electric field becomes larger, the energy of ions entering the photooxidation film and semiconductor layer increases accordingly. Consequently, from the plasma, high-energy ions enter the photooxidation film and semiconductor film, with the result that the photooxidation film and semiconductor film are damaged by the high-energy ions.

### BRIEF SUMMARY OF THE INVENTION

It is the present invention to provide an insulating film forming method capable of forming an insulating film of good film quality on a substrate to be processed by suppressing damage done to the substrate and the insulating film.

According to a first embodiment of the present invention, there is provided an insulating film forming method of forming an insulating film with a plasma film forming apparatus which includes a processing vessel with an electromagnetic wave incident face, first gas introducing openings, and second gas introducing openings made in a position farther away from the electromagnetic wave incident face than the first gas introducing openings, the insulating film forming method comprising: a step of supplying a first gas for producing plasma from the first gas introducing openings to the processing vessel; and a step of supplying a second gas including at least one of organic silicon compound gas and organic metallic compound gas and at least one of oxygen gas and rare gas from the second gas introducing openings to the processing vessel.

According to a second embodiment of the present invention, there is provided a plasma film forming apparatus comprising: an electromagnetic wave source which outputs an electromagnetic wave for producing plasma; a processing vessel which has an electromagnetic wave incident face connected to the output of the electromagnetic wave source via an electromagnetic wave supply waveguide; first gas introducing openings which are made in the processing vessel and supply a first gas as plasma producing gas; and second gas introducing openings which are provided farther away from the electromagnetic wave incident face than the first gas introducing openings and supply gas including at least one of organic silicon compound gas and organic metallic compound gas and at least one of oxygen gas and rare gas.

In the insulating film forming method of the first embodiment and the plasma film forming apparatus of the second embodiment, since gas including at least one of organic silicon compound gas and organic metallic compound gas and at least one of oxygen gas and rare gas is used as the second gas, an insulating film (such as an silicon oxide film or a metal oxide film) can be formed more uniformly than when only either organic silicon compound gas or organic metallic compound gas is used.

In addition, for example, use of surface-wave plasma enables a high-energy plasma region to be localized in a position away from an object to be processed on which an insulating film is to be formed. This helps suppress ion damage done to the object to be processed and the insulating film on the object.

Moreover, the first gas is supplied to the processing vessel from a region closer to the electromagnetic wave incident face than the second gas. In the region closer to the electromagnetic wave incident face, since electrons are accelerated directly by an electric field produced by electromagnetic waves, the energy of electrons is high. Therefore, plasma can be produced efficiently in the processing vessel using the first gas. In addition, since the electromagnetic wave is shielded by high-density plasma in a region away from the electromagnetic wave incident face, the excessive decomposition of the organic silicon compound or organic metallic compound included in the second gas can be suppressed. As a result, it is possible to form on the object an insulating film which has less oxygen deficiency, is uniform, excels in step covering properties, and has a good film quality.

According to a third embodiment of the present invention, there is provided an insulating film forming method comprising: a step of providing a substrate to be processed in a processing vessel with an electromagnetic wave incident face which an electromagnetic wave enters; a step of not only introducing a first gas including at least one of rare gas and oxygen gas from a position whose distance from the electromagnetic wave incident face is less than 10 mm into the processing vessel but also introducing a second gas including an organic silicon compound from a position whose distance from the electromagnetic wave incident face is 10 mm or more into the processing vessel separately from the first gas; and a step of depositing silicon oxide on the substrate by causing an electromagnetic wave to enter the processing vessel through the electromagnetic wave incident face to produce surface-wave plasma using the first and second gases in the processing vessel.

According to a fourth embodiment of the present invention, there is provided an insulating film forming method comprising: a step of providing a substrate to be processed in a processing vessel with an electromagnetic wave incident face that an electromagnetic wave enters; a step of not only introducing a first gas including at least one of rare gas and oxygen gas from a position whose distance from the electromagnetic wave incident face is less than 10 mm into the processing vessel but also introducing a second gas including an organic metallic compound from a position whose distance from the electromagnetic wave incident face is 10 mm or more into the processing vessel separately from the first gas; and a step of depositing metal oxide on the substrate by causing an electromagnetic wave to enter the processing vessel through the electromagnetic wave incident face to produce surface-wave plasma using the first and second gases in the processing vessel.

When an electromagnetic wave is caused to enter the processing vessel through the electromagnetic wave incident face, the first and second gases are excited, producing plasma, which increases the electron density in the plasma near the electromagnetic wave incident face. As the electron density in the plasma near the electromagnetic wave incident face increases, it is difficult for the electromagnetic wave to propagate in the plasma, with the result that the electromagnetic wave attenuates in the plasma. Accordingly, the electromagnetic wave does not reach a region away from the electromagnetic wave incident face, which limits a region where the first and second gases are excited by the electromagnetic wave to the vicinity of the electromagnetic wave incident face. This is a state where surface-wave plasma is being produced.

Specifically, in the state where surface-wave plasma is being produced, a region where the compound is ionized by the energy produced by the electromagnetic wave is localized in the vicinity of the electromagnetic wave incident face. That is, the state of surface-wave plasma differs according to the distance from the electromagnetic wave incident face. Since in the state where surface-wave plasma is being produced, a sheath electric field appearing near the surface of the substrate is small, the incident energy of ions to the substrate is low and therefore damage done to the substrate by the ions is small.

The boundary of the region where surface-wave plasma is produced is the boundary between the electromagnetic wave incident face (the dielectric windows) and the internal space of the processing vessel (the region to which the first gas is supplied). In the state where surface-wave plasma is being produced, the region where the energy of plasma is high, that is, the region where electromagnetic waves arrive and directly excite the first and second gases, can be known from the skin depth. The skin depth is the distance from the electromagnetic wave incident face to the position at which the electric field of the electromagnetic wave attenuates to 1/e. Its value depends on the electron density near the electromagnetic wave incident face.

In the state where surface-wave plasma is being produced, high-density plasma is being produced in a region closer to the electromagnetic wave incident face than the skin depth. In a region farther away from the electromagnetic wave incident face than the skin depth (or a region off the skin depth), electromagnetic waves are shielded by high-density plasma and therefore do not reach the region, with the result that oxygen radicals arrive in the form of diffusion flux.

Therefore, when surface-wave plasma is produced in the processing vessel and an insulating film is formed on a substrate to be processed in the processing vessel, a second gas including organic silicon compound gas or organic metallic compound gas is supplied from a position whose distance from the electromagnetic wave incident face is larger than the skin depth, the excessive decomposition of the organic silicon compound or organic metallic compound can be suppressed.

In addition, oxygen radicals are caused to react chemically with the organic silicon compound or organic metallic compound efficiently. Therefore, it is possible to form an insulating film (a silicon oxide film or a metal oxide film) in which the substrate has less oxygen deficiency and which is uniform, excels in step covering properties, and has a good film quality.

The skin depth δ can be found from equation (1).

$$δ = \frac{1}{\sqrt{( \frac{{ω}^{2}}{{C}^{2}} ) ( \frac{{n}_{e}}{{n}_{c}} - 1 )}} \qquad ( 1 )$$

where
ω: the angular frequency of electromagnetic wave
c: the speed of light in a vacuum (constant)
nₑ: the electron density
n_{C}: the cutoff density

The cutoff density n_{C} can be found from the following equation (2):

$${n}_{c} = \frac{{ɛ}_{0} {m}_{e} {ω}^{2}}{{q}^{2}} \qquad ( 2 )$$

where
∈₀: the permittivity in a vacuum (constant)
mₑ: the mass of an electron (constant)
ω: the angular frequency of electromagnetic wave
e: the elementary charge (constant)

The dispersion relation of surface-wave plasma is expressed by the following equation (3):

$${k}_{x} = \frac{ω}{C} \sqrt{\frac{{ɛ}_{d} ( {ω}_{p}^{2} - {ω}^{2} )}{{ω}_{p}^{2} - ( 1 + {ɛ}_{d} ) {ω}^{2}}} \qquad ( 3 )$$

where
ω: the angular frequency of electromagnetic wave
c: the speed of light in a vacuum (constant)
∈_{d}: the permittivity of the dielectric window
ωₚ: the angular frequency of plasma The angular frequency ωₚ of plasma can be found from the following equation (4):

$${ω}_{p} = \sqrt{\frac{{e}^{2} {n}_{0}}{{ɛ}_{0} {m}_{e}}} \qquad ( 4 )$$

where
e: the elementary charge (constant)
n₀: the electron density
∈₀: the permittivity in a vacuum (constant)
mₑ: the mass of an electron (constant)

For a surface wave to propagate over the surface of the boundary between the electromagnetic wave incident face (dielectric windows), the denominator in equation (3) has to take a positive value. Therefore, taking equation (4) into account, equation (5) has to be satisfied.

$${n}_{0} ≧ \frac{{ɛ}_{0} {m}_{e} ( 1 + {ɛ}_{d} )}{{e}^{2}} {ω}^{2} \qquad ( 5 )$$

where
n₀: the electron density
∈₀: the permittivity in a vacuum (constant)
mₑ: the mass of an electron (constant)
∈_{d}: the permittivity of the dielectric window
e: the elementary charge (constant)
ω: the angular frequency of electromagnetic wave

An electron density n₀ necessary for a surface wave to propagate over the boundary surface of plasma is determined when synthetic quartz (a relative permittivity of 3.8) and aluminum (a relative permittivity of 9.9) are used at 2.45 GHz, 5.58 GHz, and 22.125 GHz, the frequencies used without determining the maximum allowed value as exceptions to the allowed value of electric field strength produced by a fundamental wave or spurious emission for use of electromagnetic waves for industrious purposes in Japan (Article 65 of the Radio Equipment Regulations and General Post Office Notice No. 257). Calculating the skin depths at that time gives Table 1. That is, when complete surface-wave plasma is produced using dielectric windows whose relative permittivity is 3.8 or more at a frequency of 2.45 GHz or more, the skin depth becomes 10 mm or less.

TABLE 1

Skin depth [mm]

| | Quartz | Aluminum |
|---|---|---|
| 2.45 GHz | 10.0 | 6.2 |
| 5.8 GHz | 4.2 | 2.6 |
| 22.125 GHz | 1.1 | 0.7 |

In the processes using microwaves, a high-frequency power supply of the aforementioned frequencies, that is, 2.45 GHz, 5.8 GHz, and 22.125 GHz, is frequently used. The material for dielectric windows is generally quartz or aluminum. Therefore, it is conceivable that, if quartz dielectric windows are used and the distance from the electromagnetic wave incident face is larger than the skin depth δ at a frequency of 2.45 GHz, that is, 10 mm or more, electromagnetic waves are shielded by high-density plasma and therefore do not reach the substrate, with the result that oxygen radicals arrive in the form of diffusion flux.

Furthermore, the inventors have found that introducing the second gas into the processing vessel from a position where the electron temperature is 2 eV or less suppresses the excessive decomposition of the organic silicon compound or organic metallic compound. FIG. 18 shows the relationship between the distance from the electromagnetic wave incident face and the electron temperature. As shown in FIG. 18, even when the type of first gas and the partial pressure for producing plasma are changed, the electron temperature is about 2 eV or less in a region 10 mm or more away from the electromagnetic wave incident face. Therefore, it is seen that this does not conflict with the above reasoning.

Furthermore, the inventors have found that introducing the second gas into the processing vessel from a position at which the electron density decreases to 50% or less of that at the electromagnetic wave incident face suppresses the excessive decomposition of the organic silicon compound or organic metallic compound. FIG. 19 shows the relationship between the distance from the electromagnetic wave incident face and the electron density. As shown in FIG. 19, even when the type of first gas and the partial pressure for producing plasma are changed, the electron density decreases to 50% or less of that at the electromagnetic wave incident face. Therefore, it is seen that this does not conflict with the above reasoning.

From these results, the inventors have found that introducing the second gas into the processing vessel from a position 10 mm or more away from the electromagnetic wave incident face enables an insulating (a silicon oxide film or a metal oxide film) which has less oxygen deficiency, is uniform, and excels in step covering properties to be formed on a substrate to be processed with almost no ion damage.

As described above, in the insulating film forming methods related to the third and fourth embodiment, an insulating film is formed on a substrate using surface-wave plasma. Specifically, a first gas including at least one of rare gas and oxygen gas is introduced into the processing vessel from a position whose distance from the electromagnetic wave incident face is less than 10 mm. At the same time, a second gas including an organic silicon compound is introduced into the processing vessel from a position whose distance from the electromagnetic wave incident face is 10 mm or more.

As described above, use of surface-wave plasma enables a high-energy plasma region to be localized in a position away from the substrate to be processed. As a result, the sheath electric field near the substrate becomes smaller, which reduces the energy of ions entering the substrate. Therefore, it is possible to suppress ion damage done to the substrate and the insulating film on the substrate.

Moreover, the first gas is introduced into the processing vessel from a position whose distance from the electromagnetic wave incident face is less than 10 mm. In the region whose distance from the electromagnetic wave incident face is less than 10 mm, since electrons are accelerated directly by an electric field produced by electromagnetic waves, the energy of electrons is high. Therefore, oxygen radicals can be produced efficiently in the processing vessel.

In addition, the second gas is introduced into the processing vessel from a position whose distance from the electromagnetic wave incident face is 10 mm or more. In the region whose distance from the electromagnetic wave incident face is 10 mm or more, since the electromagnetic wave is shielded by high-density plasma, the excessive decomposition of the organic silicon compound or organic metallic compound can be suppressed. As a result, it is possible to form on the substrate an insulating film which in which the object to be processed has less oxygen deficiency and which is uniform, excels in step covering properties, and has a good film quality.

Moreover, in most of the positions 10 mm or more away from the electromagnetic wave incident face, the electron temperature is 2 eV or less. In such a low electron temperature region, that is, in a region where the energy of electrons is so low that the excessive decomposition of the organic silicon compound or organic metallic compound caused by the collision of electrons is suppressed, the oxygen radicals arriving in diffusion flux are caused to react with the organic silicon compound or organic metallic compound, thereby depositing an insulating film on the substrate. This makes it possible to form an insulating which has less oxygen deficiency, is uniform, and excels in step covering properties, and has good film quality without causing almost any damage to the substrate.

Furthermore, in most of the positions 10 mm or more away from the electromagnetic wave incident face, the electron density has decreased to 50% or less of that at the electromagnetic wave incident face. In such a low electron density region, that is, in a region where the collision frequency of electrons with the process gas is so low that the excessive decomposition of the organic silicon compound or organic metallic compound caused by the collision of electrons is suppressed, the oxygen radicals arriving in diffusion flux are caused to react with the organic silicon compound or organic metallic compound, thereby depositing an insulating film on the substrate. This makes it possible to form an insulating which has less oxygen deficiency, is uniform, and excels in step covering properties, and has good film quality without causing almost any damage to the substrate.

In the insulating film forming methods related to the third and fourth embodiments and in the insulating film forming method related to the fifth embodiment explained later, such a substrate as a glass substrate, a quartz glass substrate, a ceramic substrate, a resin substrate, or a silicon wafer may be used as “a substrate to be processed.” Moreover, “a substrate to be processed” may be such that a semiconductor layer of single-crystal silicon, polycrystalline silicon formed by laser crystallization or solid-phase crystallization, microcrystalline silicon, or amorphous silicon is formed on the above-described substrate. Furthermore, “a substrate to be processed” may be such that semiconductor layers and insulating films are stacked one on top of another in random order on the above-described substrate. In addition, “a substrate to be processed” may be such that a circuit element or a part of a circuit element is formed which is constructed by staking semiconductor layers and insulating films one on top of another in random order.

When the insulating film forming method of the third embodiment is implemented, it is desirable that the second gas should include, as organic silicon compounds, one or more of tetra-alkoxy silane, vinyl alkoxy silane, alkyl tri-alkoxy silane, phenyl tri-alkoxy silane, polymethyl disiloxane, and polymethyl cyclo tetra-siloxane. This makes it possible to form a silicon oxide film of good film quality on the substrate.

When the insulating film forming method of the fourth embodiment is implemented, it is desirable that the second gas should include, as an organic metallic compound, any one of tri-methyl aluminum, tri-ethyl aluminum, tetra-propoxy zirconium, penta-ethoxy tantalum, and tetra-propoxy hafnium. Selecting tri-methyl aluminum or tri-ethyl aluminum enables an aluminum oxide film to be formed on the substrate to be processed. Selecting tetra-propoxy zirconium enables a zirconium oxide film to be formed on the substrate. Selecting penta-ethoxy tantalum enables a tantalum oxide film to be formed on the substrate. Selecting tetra-propoxy hafnium enables a hafnium oxide film to be formed on the substrate. Hafnium oxide and zirconium oxide have higher permittivity than that of silicon oxide. Therefore, selecting tetra-propoxy hafnium or tetra-propoxy zirconium makes it possible to form an insulating film which has better electric insulation than a silicon oxide film.

When the insulating film forming methods according to the third and fourth embodiment are implemented, it is desirable that the first gas should include at least one of helium, neon, argon, krypton, and xenon. Most of the organic silicon compounds and organic metallic compounds include oxygen in their component elements. Therefore, the first gas does not necessarily have to include oxygen gas. Causing the first gas to include at least one of helium, neon, argon, krypton, and xenon enables oxygen radicals to be produced in the processing vessel and an insulating film to be formed on the substrate to be processed.

It is more desirable that the first gas should include oxygen gas and at least one rare gas of helium, neon, argon, krypton, and xenon. This makes it possible to produce more oxygen radicals in the processing vessel, which enables an insulating film with less oxygen deficiency to be formed on the substrate.

When the first gas includes oxygen gas, it is desirable that the flow rate at which oxygen gas is supplied to the processing vessel should be larger than the flow rate at which the second gas is supplied to the processing vessel. This enables more oxygen radicals to be present than the second gas below the position at which the second gas is introduced. As a result, since the oxidation of the silicon atoms in the organic silicon compound or the metal atoms in the organic metallic compound is accelerated, it is possible to form a high-quality oxide film with less oxygen deficiency.

According to a fifth embodiment of the present invention, there is provided an insulating film forming apparatus comprising: a processing vessel which has an electromagnetic wave incident face that an electromagnetic wave enters and enables a substrate to be processed to be provided therein; a first gas supply system which has a first gas introducing portion that introduces a first gas including at least one of rare gas and oxygen gas into the processing vessel and which is provided in the processing vessel; and a second gas supply system which has a second gas introducing portion that introduces a second gas including an organic silicon compound or an organic metallic compound into the processing vessel and which is provided in the processing vessel, the distance between the first gas introducing portion and the electromagnetic wave incident face being set to less than 10 mm, the distance between the second gas introducing portion and the electromagnetic wave incident face being set to 10 mm or more, and surface-wave plasma being capable of being produced using the first and second gases in the processing vessel.

In the insulating film forming apparatus of the fifth embodiment, the distance between the first gas introducing portion for introducing the first gas and the electromagnetic wave incident face is set to less than 10 mm and the distance between the second gas introducing portion for introducing the second gas and the electromagnetic wave incident face is set to 10 mm or more. This makes it possible to supply the first gas to a region where the density of plasma is relatively high. Moreover, the second gas including an organic silicon compound or an organic metallic compound can be supplied to a region where the electromagnetic wave is shielded by high-density plasma and does not arrive. As a result, the excessive decomposition of the organic silicon compound or organic metallic compound caused by the collision of electrons can be suppressed.

Therefore, use of the insulating film forming apparatus of the fifth embodiment makes it possible to form a high-quality insulating film which has less oxygen deficiency, has good film quality, and excels in step covering properties.

To produce oxygen radicals efficiently in the processing vessel, it is preferable to supply oxygen to a region near the dielectric member, particularly a region where electromagnetic waves arrive and directly excite the gas even in a surface-wave plasma state, that is, a region represented by the skin depth. That is, when the first gas including oxygen gas is used, it is preferable to supply the first gas to the region represented by the skin depth.

Accordingly, when the insulating film forming method of the fifth embodiment, it is desirable that the first gas including oxygen gas should be used and that the first gas introducing portion should be provided in a region where the distance between the first gas introducing portion and the electromagnetic wave incident face is smaller than the skin depth of surface-wave plasma or be formed integrally with the dielectric member. This enables oxygen to be supplied to the region where electrons are accelerated directly by the electric field produced by electromagnetic waves, which makes it possible to decompose the first gas supplied from the first gas supply system efficiently near the dielectric member and produce oxygen radicals efficiently. In addition, oxygen radicals produced near the dielectric member from the first gas supplied from the first gas supply system can be caused to react with the second gas sufficiently. As a result, it is possible to form an insulating film of good film quality which has less oxygen deficiency, is uniform, and excels in step covering properties.

Since most of the organic silicon compounds and organic metallic compounds have a higher boiling point than that of monosilane. Therefore, in a case where an insulating film is formed using the insulating film forming apparatus disclosed in Jpn. Pat. Appln. KOKAI Publication 2002-299241, when a compound whose boiling point is high, such as an organic silicon compound or an organic metallic compound, is used as a process gas, a part of the process gas is liquefied, which might block up part of a plurality of gas discharge openings made in the process gas shower plate. When the process shower plate is blocked up, the process gas might not be supplied stably to the processing vessel or the supply of the process gas might become non-uniform.

Therefore, in the insulating film forming apparatus disclosed in Jpn. Pat. Appln. KOKAI Publication 2002-299241, the amount of the organic silicon compound gas supplied is liable to be non-uniform. Since the insulating film forming speed depends on the amount of the process gas supplied, if the process gas is not supplied to the processing vessel stably or the amount supplied is non-uniform, the uniformity of the film thickness is impaired.

For this reason, when the insulating film forming method of the fifth embodiment is implemented, it is desirable that the second gas supply system should be provided with heating means. This makes it possible to keep such a specific temperature as enables the second gas including an organic silicon compound or an organic metallic compound to be introduced from the gas introducing portion of the second gas supply system uniformly.

When the second gas supply system is provided with heating means, it is desirable that the heating means should be capable of keeping a substrate to be processed at a temperature in the range of about 80° C. to 200° C. Keeping the second gas introducing portion at a temperature in the range of 80° C. to 200° C. makes it possible to suppress fluctuations in the amount of gas supplied caused by the liquefaction of the second gas and form an insulating film with a stable film thickness, even when a high-boiling-point gas, such as an organic silicon compound or an organic metallic compound.

It is desirable that the heating means should be provided outside the processing vessel, while being thermally connected to the second gas supply system. This makes it possible to heat the second gas supply system without complicating its configuration. For example, the heating means may be such that a circulation path is provided in the wall of the second gas supply system and high-temperature fluid (high-temperature gas or high-temperature liquid) is caused to flow in the circulation path. With this configuration, causing the high-temperature fluid to circulate through the inside of the wall enables heat energy to be transmitted to the whole of the second gas supply system quickly. Therefore, the second gas supply system can be heated uniformly. For example, a heater may be used as the heating means. The present invention is not limited to this.

Furthermore, in the insulating film forming apparatus disclosed in Jpn. Pat. Appln. KOKAI Publication 2002-299241, the process gas is introduced into the process gas shower plate from one end of the shower plate and is discharged from a plurality of gas discharge openings made in the process gas shower plate, while flowing through the shower plate. Therefore, the amount of process gas discharged from the openings made in the plate is larger at the end at which organic silicon compound gas is introduced and decreases as the distance from the end increases. As described above, when the process gas is not supplied to the processing vessel stably or the amount of the process gas supplied is non-uniform, the uniformity of the film thickness is impaired.

For this reason, when the insulating film forming method of the fifth embodiment is implemented, it is desirable that the second gas introducing portion should be composed of a shower plate having a plurality of gas injection holes in it and that the aperture ratio per unit area of the gas injection holes should be set so that the conductance (the reciprocal of physical resistance) of the gas injection holes to the gas flow may be smaller in the upstream of the gas flow in the shower plate and the conductance of the gas injection holes to the gas flow may be larger in the downstream of the gas flow in the shower plate. Specifically, for example, the aperture ratio per unit area of the gas injection holes is set so as to be smaller in the upstream of the gas flow in the shower plate and larger in the down stream of the gas flow. More preferably, the conductance of the gas injection holes (the aperture ratio per unit area of the gas injection holes) should be so set that the distribution of the amount of the second gas supplied from the shower plate to the processing vessel becomes substantially uniform. This enables the second gas to be supplied to the processing vessel uniformly, which makes it possible to form an insulating film of good uniformity on the substrate to be processed.

When the gas introducing portion is made of a shower plate divided by partition walls having openings in them, it is desirable that a plurality of partition walls to adjust the flow of the gas in the shower plate should be provided in such a manner that the conductance of the partition walls to the gas flow is larger in the upstream of the gas flow in the shower plate and is smaller in the downstream of the gas flow in the shower plate and that the gas injection holes should be provided for the regions divided by the partition walls in a one-to-one correspondence. Specifically, the partition walls should be set smaller in height in the upstream of the gas flow in the shower plate and larger in the downstream of the gas flow. More preferably, the size and position of each partition wall should be so set that the distribution of the amount of the second gas supplied from the shower plate is practically uniform. With this setting, the flow of the second gas in the shower plate is controlled, enabling the second gas to be supplied to the processing vessel uniformly, which makes it possible to form an insulating film of good uniformity on the substrate to be processed.

Furthermore, when the second gas introducing portion is composed of a shower plate having a plurality of gas injection holes in it, it is desirable that a first gas chamber having a gas inlet through which the second gas is introduced and a second gas chamber having a plurality of gas injection holes in it should be provided in the shower plate in such a manner that they are connected to one another via a diffuser plate having a plurality of openings to adjust the gas flow between the first and second gas chambers and that the aperture ratio per unit area of the openings is so set that the conductance of the openings to the gas flow is smaller in the upstream of the gas flow in the shower plate and larger in the downstream of the gas flow in the shower plate. Specifically, for example, the aperture ratio per unit area of the openings to the gas flow should be set so as to be smaller in the upstream of the gas flow in the shower plate and larger in the down stream of the gas flow. More preferably, the conductance of the openings (the aperture ratio per unit area of the openings) should be so set that the distribution of the amount of the second gas supplied from the shower plate to the processing vessel becomes substantially uniform. With this setting, the flow of the second gas is controlled in the shower plate, enabling the second gas to be supplied to the processing vessel uniformly, which makes it possible to form an insulating film of good uniformity on the substrate to be processed.

Moreover, when the insulating film forming apparatus of the fifth embodiment is implemented, the part of the processing vessel on which the second gas supply system is provided should be made of dielectric. With this configuration, the effect of the second gas introducing portion on the electromagnetic field and plasma is reduced in the transient state during the time elapsed until plasma at the beginning of discharging reaches a surface-wave plasma state, as compared with a case where conductive material, such as metal, is used, with the result that stable plasma discharging is realized.

Furthermore, when the insulating film forming apparatus of the fifth embodiment is implemented, it is desirable that the antenna should have one or more waveguide slot antennas. With this configuration, an antenna which has less dielectric loss and withstands a large amount of power, making it easy to make an insulating film forming apparatus larger. To obtain such an insulating film forming apparatus as forms an insulating film on a large substrate applied to a large liquid-crystal display device, it is more desirable that a plurality of waveguide slot antennas should be arranged side by side so as to face the outer surfaces of the dielectric members. The antenna is not limited to waveguide slot antennas. It may be composed of other types of antennas, as long as they can radiate electromagnetic waves toward the processing vessel.

Furthermore, an insulating film forming method according to an embodiment of the present invention comprises: a step of forming a first insulating film on a substrate to be processed by oxidizing the surface to be processed of the substrate with oxygen atom active species produced using a first gas; and a step of forming a second insulating film on the first insulating film by causing the active species produced from surface-wave plasma to make a second gas supplied to the vicinity of the substrate react chemically.

An insulating film forming method according to an embodiment of the present invention comprises: a step of forming a first insulating film on a substrate to be processed by oxidizing the surface to be processed of the substrate with oxygen atom active species; and a step of forming a second insulating film on the first insulating film by chemical vapor deposition (CVD) using surface-wave plasma. In this method, the step of forming the second insulating film is not restricted to chemical vapor deposition.

Here, surface-wave plasma will be explained. Generally, when a specific process gas is introduced into the processing vessel and at the same time, an electromagnetic wave enter the processing vessel, the electromagnetic wave excites the process gas, which produces plasma, with the result that the electron density in the plasma near electromagnetic wave incident face of the inside face of the processing vessel increases. As the electron density in the plasma near the electromagnetic wave incident face increases, it is difficult for the electromagnetic wave to propagate in the plasma, with the result that the electromagnetic wave attenuates in the plasma. Since the electromagnetic wave does not reach a region away from the electromagnetic wave incident face, a region where the process gas is excited by the electromagnetic wave is limited to the vicinity of the electromagnetic wave incident face. This is a state where surface-wave plasma is being produced.

That is, in a state where surface-wave plasma is being produced, the following can be said. A region where the plasma gas is ionized as a result of the application of energy from the electromagnetic wave is localized near the electromagnetic wave incident face. Placing the substrate to be processed in a position away from the electromagnetic wave incident face enables the electron temperature near the surface to be process of the substrate to be kept low. That is, an increase in the sheath electric field appearing near the surface of the substrate to be processed is suppressed, which keeps the incident energy of ions to the substrate low. As a result, it is possible to suppress damage to the substrate caused by ions.

In the insulating film forming method of the embodiment, an oxide film is formed on the substrate in the oxidation of the substrate by oxygen atom active species performed in a first step (a step of forming a first insulating film), while oxygen atom active species are diffusing within the substrate. As a result, it is possible to make the interface between the substrate and the oxide film have few defects.

In a second step (a step of forming a second insulating film), it is desirable that a second insulating film should be formed by a method of reducing ion damage done to the first insulating film (oxide film) formed in the first step and to the interface between the substrate and the first insulating film so as to impair the substrate and the interface as little as possible. To achieve this, the second step is to cause the second gas to react chemically with active species produced from surface-wave plasma, thereby forming a second insulating film on the first insulating film.

The second step may use, for example, CVD using surface-wave plasma. Specifically, as described above, in a state where surface-wave plasma is being produced, since a sheath electric field appearing near the surface to be process of the substrate is small, ion damage to the substrate to be process, the first insulating film, or the interface between the substrate and the first insulating film can be suppressed. That is, use of chemical vapor deposition using surface-wave plasma in the second step makes it possible to form a film with less damage necessary in the second step. As a result, it is possible to form an insulating film (a stacked film of the first insulating film and the second insulating film) with excellent electric properties on the substrate.

As described above, in the insulating film forming method of the embodiment, after the first insulating film is formed by oxidizing the surface to be processed of the substrate using oxygen atom active species produced by the first gas, surface-wave plasma is produced. The second gas supplied to the vicinity of the substrate is caused to react chemically with the active species produced from the surface-wave plasma, thereby forming a second insulating film on the first insulating film, with the result that an insulating film (a stacked film of the first insulating film and the second insulating film) is formed on the substrate to be processed. Accordingly, it is possible to form an insulating film on the substrate, with a good property of the interface between the substrate and the insulating film. Moreover, since the second insulating film is formed by causing the second gas supplied to the vicinity of the substrate to react chemically with the active species produced from the surface-wave plasma, ion damage to the substrate, the first insulating film, or the interface between the substrate and the first insulating film can be suppressed when the second insulating film is formed on the first insulating film.

Therefore, according to the insulating film forming method of the embodiment, it is possible to form an insulating film of good film quality on a substrate to be processed, while suppressing damage to the substrate and the insulating film formed on the substrate.

When the insulating film forming method of the embodiment is implemented, it is desirable that the oxygen atom active species should be produced by surface-wave plasma produced as a result of the first gas being excited by electromagnetic waves in the process of forming the first insulating film. As described above, in a state where surface-wave plasma is being produced, the electron temperature is low near the substrate to be processed and therefore ion damage to the substrate is small. Therefore, use of plasma oxidation by surface-wave plasma as the oxidation of the substrate enables the interface between the substrate and the oxide film to have fewer defects.

Moreover, when the insulating film forming method of the embodiment is implemented, it is desirable that the step of forming the first insulating film and the step of forming the second insulating film should be carried out sequentially in one processing vessel without vacuum break. In other words, it is desirable that the step of forming the first insulating film and the step of forming the second insulating film should be carried out sequentially without opening the processing vessel to atmosphere. This prevents the interface between the first insulating film and the second insulating film from being contaminated with ambient air, which suppresses the contamination of the insulating film (the stacked film of the first insulating film and the second insulating film). Moreover, there is no need to transport the substrate to be processed in proceeding from the step of forming the first insulating film to the step of forming the second insulating film. Consequently, the time required for the processing can be shortened, which increases the efficiency of the processing.

In a transient state during the time elapsed until plasma at the beginning of discharging reaches a surface-wave plasma state, electromagnetic waves reached the vicinity of the substrate to be processed. Thus, in such a transient state, damage can be done to the substrate and the first insulating film. The insulating film formed in such a transient state might have a worse film quality than an insulating film formed in a state where surface-wave plasma is being produced.

Therefore, when plasma discharging is stopped after the formation of the first insulating film and then is started again, damage can be done to the substrate or the first insulating film or a film of poor film quality can stay behind between the first and second insulating films.

To suppress these things, when the insulating film forming method of the embodiment is implemented, the step of forming the first insulating film is to supply the first gas after transporting the substrate. This step further includes a step of producing surface-wave plasma using the first gas in the processing vessel by radiating an electromagnetic wave, producing oxygen atom active species, and oxidizing the surface to be processed of the substrate with the oxygen atom active species, thereby forming the first insulating film on the substrate. It is desirable that the step of forming the second insulating film should further includes a step of, while supplying the first gas continuously and performing plasma discharging of the surface-wave plasma continuously, further supplying the second gas to the processing vessel and depositing oxide on the first insulating film by chemical vapor deposition using the surface-wave plasma, thereby forming the second insulating film. This process makes it possible to suppress not only damage done to the substrate and first insulating film by high-energy ions as in a conventional method and but also the remaining of a film of poor film quality formed in a transient state at the beginning of discharging between the first insulating film and the second insulating film.

In this case, it is desirable that the first gas and second gas should be supplied separately. This makes it possible to reduce a fluctuation in the flow of the first gas caused by the second gas at the beginning of the supply of the second gas in the step of forming the second insulating film. Since this suppresses a fluctuation in the plasma produced in proceeding from the step of forming the first insulating film to the step of forming the second insulating film, the discontinuity in the interface between the first insulating film and the second insulating film can be made smaller. Consequently, it is possible to form an insulating film with higher reliability.

Furthermore, when the second gas is supplied, it is desirable that the flow rate of the second gas should be set larger than the flow rate of the first gas and that the amount of the second gas supplied should be increased stepwise. This further reduces a fluctuation in the flow of the first gas caused by the supply of the second gas at the time when the supply of the first gas is started. Accordingly, the discontinuity in the interface between the first insulating film and the second insulating film can be made much smaller.

As the first gas, for example, oxygen gas or a mixed gas including oxygen gas or rare gas may be used suitably. As the second gas, gas including at least one of silane, an organic silicon compound, and an organic metallic compound may be used suitably.

Most of the organic silicon compounds and organic metallic compounds include oxygen in their component elements. Therefore, when gas including at least either an organic silicon compound or an organic metallic compound is used as the second gas, the first gas does not necessarily have to include oxygen gas. Causing the first gas to include at least one of helium, neon, argon, krypton, and xenon enables oxygen radicals to be produced in the processing vessel and an insulating film to be formed on the substrate to be processed. It is more desirable that gas including oxygen gas and at least one rare gas of helium, neon, argon, krypton, and xenon should be used as the first gas. This makes it possible to produce more oxygen radicals in the processing vessel, which enables an insulating film with less oxygen deficiency to be formed on the substrate.

When the insulating film forming method of the embodiment is implemented, it is preferable to use, as the substrate to be processed, a substrate which has a semiconductor region at least in a part of its externally exposed region and uses the surface of the semiconductor region as the surface to be processed.

Furthermore, when the insulating film forming method of the embodiment is implemented, it is desirable that the method should further comprise a step of removing an insulating film deposited to the inside of the processing vessel by chemical vapor deposition. This makes it possible to process a subsequent substrate in the processing vessel with high cleanliness, when a plurality of substrates are processed sequentially. Since the cleanliness of the interface between the substrate and the oxide film is also improved, an insulating film of high reliability is obtained.

As the substrate to be processed, a semiconductor substrate of single-crystal silicon, polycrystalline silicon formed by laser crystallization or solid-phase crystallization, microcrystalline silicon, or amorphous silicon may be used. In addition, at least on a part of a substrate made of glass, quartz glass, ceramic, or resin, a semiconductor layer of single-crystal silicon, polycrystalline silicon formed by laser crystallization or solid-phase crystallization, microcrystalline silicon, or amorphous silicon may be formed. The resulting substrate may be used as the substrate to be processed. Moreover, on the above substrate, a circuit element or a part of a circuit element may be formed which is constructed by staking insulating films, metal layers, and semiconductor layers one on top of another. The resulting substrate may be used as the substrate to be processed.

As for the second gas including an organic silicon compound, it is desirable that the second gas should include at least one of, for example, tetra-alkoxy silane, vinyl alkoxy silane, alkyl tri-alkoxy silane, phenyl tri-alkoxy silane, polymethyl disiloxane, and polymethyl cyclo tetra-siloxane. This makes it possible to form a silicon oxide film of good film quality on the substrate.

As for the second gas including an organic metallic compound, it is desirable that the second gas should include at least one of tri-methyl aluminum, tri-ethyl aluminum, tetra-propoxy zirconium, penta-ethoxy tantalum, and tetra-propoxy hafnium. Selecting tri-methyl aluminum or tri-ethyl aluminum enables an aluminum oxide film to be formed on the substrate to be processed. Selecting tetra-propoxy zirconium enables a zirconium oxide film to be formed on the substrate. Selecting penta-ethoxy tantalum enables a tantalum oxide film to be formed on the substrate. Selecting tetra-propoxy hafnium enables a hafnium oxide film to be formed on the substrate. Hafnium oxide and zirconium oxide have higher permittivity than that of silicon oxide. Therefore, selecting tetra-propoxy hafnium or tetra-propoxy zirconium makes it possible to form an insulating film which has better electric insulation than a silicon oxide film.

When the first gas includes oxygen gas, it is desirable that the flow rate in supplying oxygen gas to the processing vessel should be set larger than the flow rate in supplying the second gas to the processing vessel. This enables more active species, such as oxygen radicals, to be present below the position at which the second gas is introduced. Since the oxidation of silicon atoms in the organic silicon compound or metal atoms in the organic metallic compound is accelerated, it is possible to form a high-quality oxide film with much less oxygen deficiency.

It is possible to provide an insulating film forming method and a plasma film forming apparatus which enable an insulating film of good film thickness uniformity to be formed with less ion damage.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view of a plasma film forming apparatus for executing an insulating film forming method according to an embodiment of the present invention;

FIG. 2 is a side view of an electromagnetic wave source included in the plasma film forming apparatus of FIG. 1;

FIG. 3 is a sectional view taken along line III-III of FIG. 1;

FIG. 4 is a sectional view taken along line IV-IV of FIG. 1;

FIG. 5 is a sectional view of another plasma film forming apparatus for executing the insulating film forming film according to the embodiment;

FIG. 6 is a sectional view taken along line VI-VI of FIG. 5;

FIG. 7 is a sectional view of an insulating film forming apparatus according to a third embodiment of the present invention;

FIG. 8 is a sectional view taken along line II-II of FIG. 1;

FIG. 9 is a sectional view taken along line III-III of FIG. 1;

FIG. 10 is a sectional view of an insulating film forming apparatus according to a fourth embodiment of the present invention;

FIG. 11 is a sectional view taken along line V-V of FIG. 4;

FIG. 12 is a sectional view of an insulating film forming apparatus according to a fifth embodiment of the present invention;

FIG. 13 is a sectional view of an insulating film forming apparatus according to a sixth embodiment of the present invention;

FIG. 14 is a sectional view of an insulating film forming apparatus according to a seventh embodiment of the present invention;

FIG. 15 is a sectional view of an insulating film forming apparatus according to an eighth embodiment of the present invention;

FIG. 16 is a sectional view of an insulating film forming apparatus usable in executing the insulating film forming method of the first embodiment;

FIG. 17 is a sectional view of an insulating film forming apparatus usable in executing the insulating film forming method of the second embodiment;

FIG. 18 shows the relationship between the distance from the electromagnetic wave incident face and the electron temperature; and

FIG. 19 shows the relationship between the distance from the electromagnetic wave incident face and the electron density.

### DETAILED DESCRIPTION OF THE INVENTION

Hereinafter, referring to the accompanying drawings, a first embodiment of the present invention will be explained.

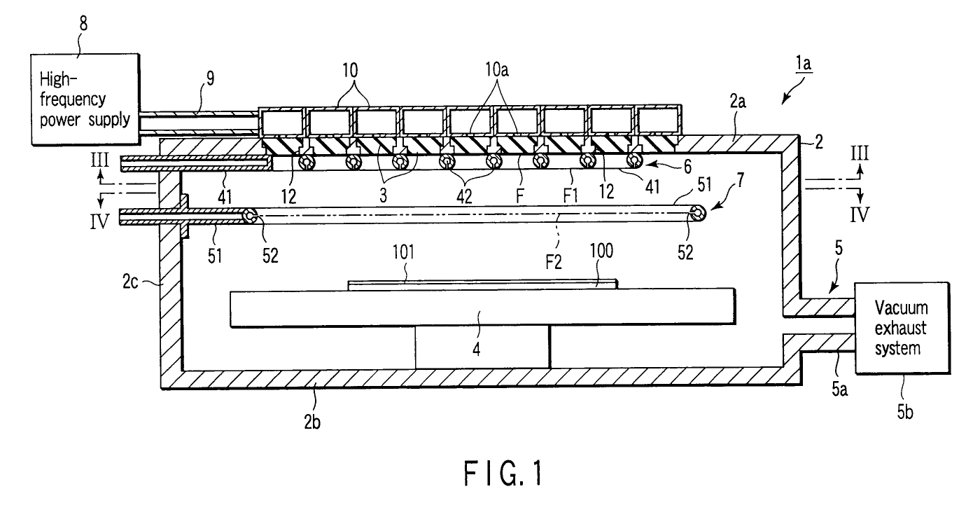

FIG. 1 shows a plasma film forming apparatus for realizing an insulating film forming method according to the embodiment. The plasma film forming apparatus la comprises a vacuum vessel 2 as a processing vessel, one or more (e.g., nine) dielectric windows 3, a substrate support table 4, a gas exhaust system 5, an upper gas supply system 6 as a first gas supply system, a lower gas supply system 7 as a second gas supply system, an electromagnetic wave source 8, an electromagnetic wave supply waveguide 9, and one or more (e.g., nine) waveguide slot antennas 10.

The vacuum vessel 2 has a top cover 2a as a top wall, a bottom wall 2b, and a sidewall 2c which connects the periphery of the top cover 2a and the periphery of the bottom wall 2b hermetically. The vacuum vessel 2 is designed to have such strength as enables its inside to be depressurized to a vacuum or to its vicinity. A material which is hermetic and emits no gas, such as glass, or metal material, such as aluminum, may be used as a material for forming the top cover 2a, bottom wall 2b, and sidewall 2c.

The top cover 2a has plurality of (for the embodiment, nine) square openings 12 are provided in parallel with one another at specific intervals in a direction going straight to this page surface. Each of the openings 12 has almost a T-shaped cross section (the upper part is wide in comparison with the lower part) in the longitudinal section. Dielectric materials are filled in the openings 12 and form the dielectric windows 3 constituting a part of the top wall of the vacuum vessel 2. These dielectric windows 3 are also designed to have such strength as enables the inside of the vacuum vessel 2 to be depressurized to a vacuum or its vicinity. As a material for forming the dielectric windows 3, a material for transmitting electromagnetic waves, such as synthetic quartz or aluminum oxide, may be used.

Each of the dielectric windows 3 is made of a long, narrow member with almost the same T-shaped cross section as a dimension of the longitudinal section of the openings 12 so as to engage with the corresponding openings 12 hermetically. The top cover 2a not only is a part of the wall of the vacuum vessel 2 but also functions as a beam which supports the dielectric windows 3. Such as the embodiment, use of a plurality of (e.g., nine) dielectric windows 3 may lower the stress applied to the individual dielectric windows 3 by atmospheric pressure, which enables the thickness of the dielectric windows 3 to be decreased.

Although not shown, the vacuum vessel 2 has a hermetically sealing mechanism which seals the spacing between the a part around dielectric window 3 of top cover 2a and the dielectric windows 3. The sealing mechanism has, for example, a groove made in the side defining the openings 12 along its circumference and an O-ring inserted in the groove.

Inside the vacuum vessel 2, the substrate support table 4 is provided which supports a substrate to be processed 100 as a material to be processed. The position of the substrate support table 4 is set so that the surface to be processed (in this embodiment, the top surface) of the substrate 100 supported on the support table 4 may be held at specified distance from below a second gas injection hole 52, for example, 25 mm below.

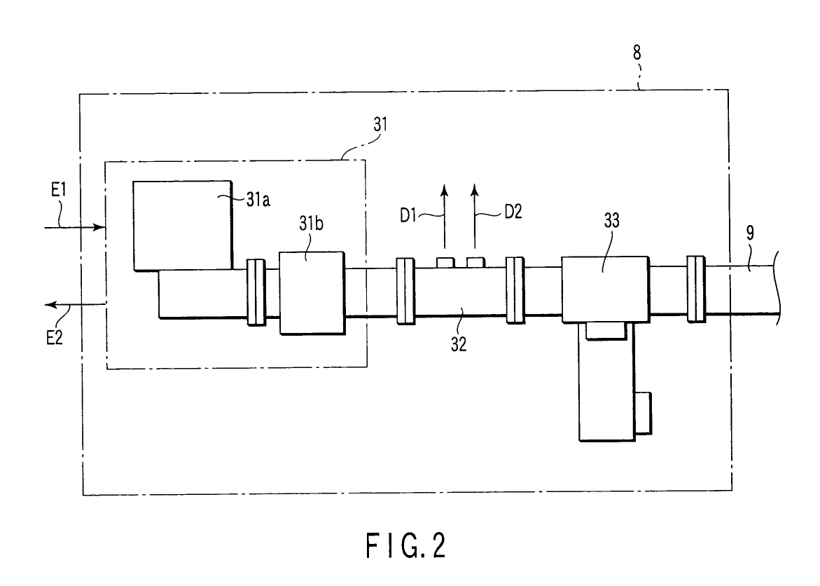

As the electromagnetic wave source 8, for example, a 2.45-GHz electromagnetic wave source may be used. As shown in FIG. 2, the electromagnetic wave source 8 includes an oscillation section 31, a power monitor 32, and an E-H tuner 33 as a matching unit. The oscillation section 31 has a magnetron 31a as an oscillator and an isolator 31b. The isolator 31b protects the magnetron 31a from reflected waves. The oscillation section 31 is cooled by a liquid-cooled chiller (not shown). In FIG. 2, arrows E1 and E2 show the flow of cooling water. The power monitor 32 monitors progressive waves and reflected waves. In FIG. 2, arrows D1 and D2 show the directions in which progressive waves and reflected waves are propagated, respectively. The E-H tuner 33 reduces the reflected waves.

In FIG. 1, outside the vacuum vessel 2, for example, on the top cover 2a, a plurality of (in the embodiment, nine) waveguide slot antennas 10 are provided for the dielectric windows in a one-to-one correspondence to introduce the electromagnetic wave into the vacuum vessel 2. Each of the waveguide slot antennas 10 has slit-like openings 10a in a part of the lower wall constituting the wall of the waveguide. Each waveguide slot antenna 10 functions as an antenna by radiating an electromagnetic wave through electromagnetic coupling near the openings 10a.

These waveguide slot antennas 10 are arranged so as to face the outside faces of the dielectric windows 3 in a one-to-one correspondence. The waveguide slot antennas 10 are connected to one another.

The waveguide slot antennas 10 are generally made of metal. Therefore, they have lower dielectric loss than antennas made of dielectric and features high resistance to a large amount of power. Moreover, since each of the waveguide slot antennas 10 are formed by metallic conduit having rectangular (a long and thin) section, a simple structure and therefore their radiation characteristic can be designed relatively accurately, they are suitable for a large-substrate plasma film forming apparatus. The insulating film forming method of the embodiment and the plasma film forming apparatus 1a are particularly suitable for a case where an insulating film is formed on a square (rectangular) substrate with a large area used for, for example, a large square liquid-crystal device of several tens of square centimeters.

One end of each of the waveguide slot antennas 10 are connected to side of the waveguide 9 which extended to be perpendicular to these antenna 10. The waveguide 9 spreads to outer of the vacuum vessel 2 and it is connected to electromagnetic wave source, such as the high-frequency power supply 8. Therefore, the electromagnetic wave generated by the high-frequency power supply 8 is directed via the waveguide 9 to the corresponding waveguide slot antenna 10, passes through the corresponding dielectric window 3, and enters the vacuum chamber 2. In this embodiment, the inside face of the dielectric window 3 (namely underside) is the electromagnetic wave incident face F.

The gas exhaust system 5 has a gas exhaust section 5a provided in the vacuum vessel 2 so as to connect to the inside of the vacuum vessel 2, and a vacuum exhaust system 5b. For vacuum exhaust system 5b, for example, the turbo molecular pump can be used. The vacuum vessel 2 can be exhausted to a specific degree of vacuum by operating the vacuum exhaust system 5b.

The upper gas supply system, namely first gas supply system 6 supplies a first gas to the vacuum vessel 2. As the first gas, for example, gas including at least one of oxygen gas and rare gas, for example, krypton gas, may be used. The upper gas supply system 6 has, for example, an upper gas introducing pipe 41 as a first gas introducing portion.

The upper gas introducing pipe 41 is made of metal, such as aluminum, stainless steel, or titanium, or dielectric materials, such as silicon oxide, aluminum oxide, or aluminum nitride. It is not limited to dielectric materials as the upper gas introducing pipe 41, however, when the effect of the upper gas introducing pipe 41 on electromagnetic fields and plasma is taken into consideration, it is desirable that the upper gas introducing pipe 41 should be made of a material with transparency to incoming electromagnetic waves, such as dielectric material. However, taking the process of forming a tube into account, it is inexpensive and easy to make the upper gas introducing pipe 41 of metal material. Therefore, when the upper gas introducing pipe 41 is made of metal material, an insulating film should be formed on the outside face of the upper gas introducing pipe 41.

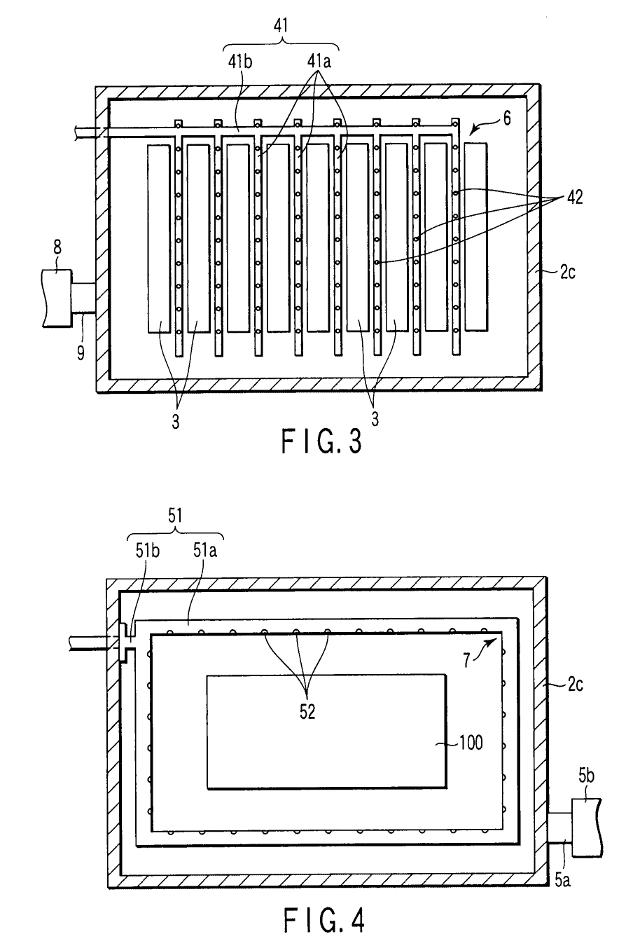

In FIG. 3, the upper gas introducing pipe 41 is provided along the inside face of the top cover 2a (beam), namely underside, in the vacuum vessel 2, keeping away from the regions where the dielectric windows 3 are formed. Specifically, the upper gas introducing pipe 41 has a plurality of (in the embodiment, eight) straight pipes 41a and one extended pipe 41b. These straight pipes 41a are laid in parallel with one another so as to run along the inside face of the top cover 2a (beam) in the vacuum vessel 2. Each straight pipe 41a spreads in parallel between adjacent the dielectric window 3. The extended pipe 41b is laid so as to be at right angles with the straight pipes 41a and connects one end of these straight pipes 41a to be in communication with one another. One end of the extended pipe 41b extends outside the vacuum vessel through the sidewall 2c of the vacuum vessel 2. To one end of the extended pipe 41b, a first gas cylinder (not shown) in which the first gas is held can be provided detachably.

At underside of each of the straight pipes 41a, there are provided plurality of first gas introducing openings for supplying the first gas for generating plasma, such as a first gas injection holes. These first gas injection holes 42 are openings downward and are provided at almost regular intervals in the longitudinal direction of the straight pipe 41a. Therefore, all first gas injection holes 42 formed at the straight pipe 41a are arranged, for example, almost in the same plane so that injection gas may be distributed uniformly. These first gas injection holes 42 are provided in positions where the distance from the electromagnetic wave incident face F is smaller than the skin depth δ of the surface wave plasma.

The lower gas supply system, namely second gas supply system 7 supplies a second gas to the vacuum vessel 2. The second gas is a mixed gas including at least one of organic silicon compound gas and organic metallic compound and including at least one of oxygen gas and diluted gas. For example, a mixed gas of tetra-ethoxy silane (TEOS) as organic silicon compound gas and oxygen gas, may be used. It is shown in FIG. 1, the lower gas supply system 7 has, for example, a lower gas introducing portion 51 as a second gas introducing portion.

Like the upper gas introducing pipe 41, the lower gas introducing portion 51 is made of metal, such as aluminum, stainless steel, or titanium, or dielectric, such as silicon oxide, aluminum oxide, or aluminum nitride. In a transient state during the time elapsed until plasma at the beginning of discharge reaches a surface wave plasma state, electromagnetic waves radiated from the dielectric windows 3 also reach the lower gas supply system 7. Therefore, if the lower gas introducing portion 51 is made of metallic material, the lower gas supply system 7 might have an effect on the generation of electromagnetic fields and plasma in the transient state. For this reason, when the effect of the lower gas introducing portion 51 on electromagnetic waves and plasma is considered, it is desirable that the lower gas introducing portion 51 should be made of a material with transparency to incoming electromagnetic waves, such as dielectric material. When the lower gas introducing portion 51 is made of metal material, it is desirable that an insulating film should be formed on the outside face of the lower gas introducing portion 51.

As shown in FIG. 4, the lower gas introducing portion 51 has a ring-shaped pipe, for example, ring-shaped pipe (ring-shaped member) 51a such as the rectangular frames-shaped formed by bending and the extended pipe 51b. The ring-shaped pipe 51a has an outer shape slightly larger than the outer edge of the substrate to be processed 100. It is desirable that the ring-shaped member 51a should be a circular-ring-shaped member when the outer shape of the substrate is circular and be a square-ring-shaped member when the outer shape is square. One end of the extended pipe 51b is connected to the ring-shaped member 51a. Other end of the extended pipe 51b extends outside the vacuum vessel 2 through the sidewall 2c of the vacuum vessel 2. To one end of extending, a second gas cylinder (not shown) in which the second gas is held can be provided detachably.

In the ring-shaped pipe 51a, there are formed second gas introducing openings, such as a plurality of second gas injection holes 52. These second gas injection holes 52 are provided at almost regular intervals inside of ring-shaped pipe 51a so as to open toward the inside of the ring-shaped pipe 51a. Specifically, it is desirable that these second gas injection holes 52 are arranged almost in the same horizontal plane. These second gas injection holes 52 are provided in positions where the distance from the electromagnetic wave incident face F is larger than the skin depth δ of the surface wave plasma.

In above configuration, the second gas should be supplied from the second gas injection holes 52 provided more away from the electromagnetic wave incident face F than the first gas injection holes 42. It is desirable that position of the first gas injection holes 42 and the second gas injection holes 52 is set so that the first gas should be supplied from a position less than 10 mm away from the electromagnetic wave incident face F to the vacuum vessel 2 and that the second gas should be supplied from a position 10 mm or more away from the electromagnetic wave incident face F to the vacuum vessel 2.

The reason of setting the first gas and the second gas supply position within process vessel is explained thereinafter.

When electromagnetic waves are caused to enter the vacuum vessel 2 from the electromagnetic wave incident face F, the first gas and the second gas are excited in the vacuum vessel 2, producing plasma, which increases the electron density in the plasma near the electromagnetic wave incident face F. As the electron density in the plasma increases near the electromagnetic wave incident face F, it becomes difficult for the electromagnetic waves to propagate in the plasma, with the result that the electromagnetic waves attenuate in the plasma. Therefore, the electromagnetic waves do not reach the regions separated from the electromagnetic wave incident face F, which limits the region where the first and second gases are excited by the electromagnetic waves to the vicinity of the electromagnetic wave incident face F. This is the state where surface-wave plasma is being produced.

In the state where surface-wave plasma is being produced, regions where a compound is ionized as a result of the application of energy from electromagnetic waves are localized near the electromagnetic wave incident face F. That is, the surface-wave plasma differs in its state according to the distance from the electromagnetic wave incident face F. Moreover, in the state where surface-wave plasma is being produced, a sheath electric field appearing near the surface of the substrate to be processed 100. Accordingly, the incident energy of ions to the substrate 100 is low, resulting in less damage to the substrate 100 caused by ions.

The boundary of the region where surface-wave plasma is produced is the boundary between the electromagnetic wave incident face (the inside face of the dielectric window 3) F and the region to which the first gas is supplied in the space of the vacuum vessel 2. In the state where surface-wave plasma is being produced, the region where the energy of plasma is high, that is, the region where electromagnetic waves arrive and directly excite the gas in the vacuum vessel 2, can be known from the skin depth. The skin depth is corresponding to the distance from the electromagnetic wave incident face F to the position at which the electric field of the electromagnetic wave attenuates to 1/e, and is dependence on the electron density near the electromagnetic wave incident face F.

In the state where surface-wave plasma is being produced, high-density plasma is being produced in a region closer to the electromagnetic wave incident face F than the skin depth. In a region farther away from the electromagnetic wave incident face F than the skin depth (or a region off the skin depth, it is defined as remote region), electromagnetic waves are shielded by high-density plasma and therefore do not reach the region, with the result that oxygen radicals and the like arrive in the form of diffusion flux.

When organic silicon compound gas and/or organic metallic compound gas (this gas is defied as special process gas) is used as process gas for forming an insulating film, it is well known that an insulating film with good coating properties is easier to obtain than when silane gas is used. This is because organic silicon compound gas and organic metallic compound gas have a larger molecular volume than silane. Therefore, in organic silicon compound gas or organic metallic compound gas, the intermediate product obtained by decomposing the organic silicon compound by plasma has a relatively large molecular volume. With its three-dimensional effect, the intermediate product adheres to the surface of the substrate in a relatively uniform manner, while migrating over the substrate. However, since the organic silicon compound and organic metallic compound have alkyl groups or the like in their skeleton, when they are decomposed excessively, the carbon atoms included in the carbon skeleton part are liable to get mixed into the formed silicon oxide in the form of impurities.

Therefore, when an insulating film 101 is formed on the substrate 100 (shown in FIG. 1) provided in the vacuum vessel 2 by producing surface-wave plasma in the vacuum vessel 2, Special process gas is supplied from the remote region, which suppresses the excessive decomposition of special process gas. Moreover, the oxygen radicals and the like decomposed and produced by surface-wave plasma can be caused to react with organic silicon compounds and/or organic metallic compounds efficiently. That is, conceivably, it is possible to form an insulating film (silicon oxide film or metal-oxide film) which has less oxygen deficiency, excellent step coating properties, and good film quality.

The skin depth δ can be found using equation (1).

From table 1, it is seen that, when the frequency of the electromagnetic wave is set to 2.45 GHz or more and the relative permittivity of the dielectric windows is set to 3.8 or more (synthetic quartz), the skin depth becomes 10 mm or less in the complete surface-wave plasma state.

In a process using microwaves as electromagnetic waves, a high-frequency power supply of the aforementioned frequencies, that is, 2.45 GHz, 5.8 GHz, and 22.125 GHz is frequently used to generate electromagnetic wave of the frequency more than above the 2.45 GHz. A material for the dielectric windows 3 is generally quartz or aluminum. Specifically, when the frequency of the high-frequency power supply is set to 2.45 GHz and the dielectric windows 3 are made of quartz, electromagnetic waves are shielded by high-density plasma and therefore do not arrive in a region where the skin depth δ is exceeded, that is, a region 10 mm or more away from the electromagnetic wave incident face F, with it is conceivable that the result that oxygen radicals and the like arrive in the form of diffusion flux.

Supplying the second gas to the vacuum vessel 2 from a position where the electron temperature is 2 eV or less suppresses the excessive decomposition of organic silicon compounds or organic metallic compounds. Even when the type of first gas and the partial pressure for producing plasma are changed, the electron temperature is about 2 eV or less in a region 10 mm or more away from the electromagnetic wave incident face F. Therefore, it is seen that this does not conflict with the above reasoning.

Furthermore, introducing the second gas into the vacuum vessel 2 from a position at which the electron density decreases to 50% or less of that at the electromagnetic wave incident face F suppresses the excessive decomposition of organic silicon compounds or organic metallic compounds. Even when the type of first gas and the partial pressure for producing plasma are changed, the electron density decreases to 50% or less of that at the electromagnetic wave incident face F. Therefore, it is seen that this does not conflict with the above reasoning.

The first gas injection holes 42 may be realized by providing a part of wall of the vacuum vessel 2 with a dielectric member having the electromagnetic wave incident face F and forming nozzles at the dielectric member.

In the embodiment, the upper gas introducing pipe 41 is so provided that the distance between a virtual plane F1 in which the first gas injection holes 42 are positioned and the electromagnetic wave incident face F is less than 10 mm, for example, 3 mm. That is, a plurality of first gas injection holes 42 are provided 3 mm below the electromagnetic wave incident face F.

In addition, the lower gas introducing portion 51 is so provided that the distance between a virtual plane F2 in which the second gas injection holes 52 are positioned and the electromagnetic wave incident face F is 10 mm or more, for example, 30 mm. That is, a plurality of second gas injection holes 52 are provided 30 mm below the electromagnetic wave incident face F.

The special process gas included in the second gas has a higher boiling point than monosilane and is liable to liquefy. Therefore, to supply the second gas to the vacuum vessel 2 stably, it is desirable that inside of the lower gas supply system 7 should be kept at suitable temperature, that is, about 80° C. to 200° C. For this reason, the lower gas supply system 7 may have heating means, such as a heater.

Next, using the apparatus, an insulating film forming method will be explained. In the embodiment, explanation will be given about a case where an insulating film 101 (a silicon oxide film in the embodiment) is formed on a substrate to be processed 100 by using krypton gas as the first gas and a mixed gas of the organic silicon compound gas such as tetra-alkoxy silane and oxygen gas as the second gas.

A substrate to be processed 100 is loaded in within the vacuum vessel automatically by the transfer means (not shown), and a substrate to be processed 100 is positioned in a predetermined position on the substrate support table 4. The gas exhaust system 5 is driven, evacuating the vacuum vessel 2 to a specific degree of vacuum. The upper gas supply system 6 supplies krypton gas, to the vacuum vessel 2 at a flow rate of, for example, 400 SCCM. The lower gas supply system 7 supplies tetra-ethoxy silane gas, at a flow rate of 35 SCCM and oxygen gas at a flow rate of 10 SCCM to the vacuum vessel 2, thereby supplying the mixed gas to the vacuum vessel 2. That is, it is desirable that the flow rate in supplying TEOS gas (the organic silicon compound gas) to the vacuum vessel 2 should be set to about more than 50% (in the embodiment, 77.8%) of the total flow rate in supplying the second gas to the vacuum vessel.

When the flow rate in supplying the special process gas (in the embodiment, tetra-ethoxy silane gas) to the vacuum vessel 2 dropped below 50% of the total flow rate in supplying the second gas to the vacuum vessel 2, the film forming speed may dropped sharply. Setting the flow rate in supplying the special process gas to the vacuum vessel 2 so as to exceed 50% of the total flow rate in supplying the second gas to the vacuum vessel 2 makes it possible to form an insulating film without decreasing the film forming speed.

It is more preferable to set the flow rate so as to exceed 70%. It is much more preferable to set the flow rate so as to be in the range of 70% or more to 90% or less.

In the state that the gas is introduced in the vacuum vessel, the high-frequency power supply is turned on. As a result, a 2.45-GHz electromagnetic wave through the waveguide 9, each waveguide slot antenna 10, and the dielectric window 3 sequentially, and it is incident in vacuum vessel 2. As a result, the first gas is excited, producing plasma, with the result that the electron density in the plasma near the electromagnetic wave incident face F increases with time. As the electron density in the plasma near the electromagnetic wave incident face F increases, this makes it difficult for the electromagnetic wave from the dielectric windows 3 to propagate in the plasma, with the result that the electromagnetic wave attenuates. Accordingly, the electromagnetic wave does not reach a region separate from the electromagnetic wave incident face F. That is, generated plasma becomes surface-wave plasma. Since the first gas is introduced into the vacuum vessel 2 from a position 3 mm away from the electromagnetic wave incident face F, that is, from a region whose distance from the electromagnetic wave incident face F is smaller than the skin depth δ, oxygen molecules are excited by high-density plasma in a state where surface-wave plasma is being produced, which produces oxygen radicals efficiently.

On the other hand, tetra-ethoxy silane gas is introduced into the vacuum vessel 2 from a position 30 mm away from the electromagnetic wave incident face F, that is, from a region whose distance from the electromagnetic wave incident face F is larger than the skin depth. Therefore, since the electromagnetic wave is shielded by high-density surface plasma and does not reach the remote region in the vacuum vessel 2 into which tetra-ethoxy silane gas has been introduced, the excessive decomposition of tetra-ethoxy silane gas by the electromagnetic wave can be suppressed. Moreover, even in a position 30 mm away from the electromagnetic wave incident face F, oxygen radicals generated by the surface plasma arrive in the form of diffusion flux, causing tetra-ethoxy silane and oxygen radicals to react with one another efficiently, which enhances the decomposition of tetra-ethoxy silane. As a result, on the surface of the substrate to be processed, silicon oxide deposits. Since tetra-ethoxy silane is a compound whose molecular volume is larger than that of monosilane, tetra-ethoxy silane adheres to the surface of the substrate 100 in a relatively uniform manner, while migrating over the substrate by its three-dimensional effect. Consequently, an insulating film (silicon oxide film) 101 of good film quality is formed on the substrate 100.

On the other hand, under the following conditions, an insulating film (silicon oxide film) was formed similarly.

The upper gas supply system 6 supplies krypton gas to the vacuum vessel 2 at a flow rate of 400 SCCM. The lower gas supply system 7 supplies tetra-ethoxy silane gas at a flow rate of 35 SCCM and oxygen gas at a flow rate of 35 SCCM or 10 SCCM to the vacuum vessel 2, thereby supplying the mixed gas to the vacuum vessel 2. That is, the flow rate in supplying TEOS gas to the vacuum vessel 2 is set so as to be about 50% or 22% of the total flow rate in supplying the second gas to the vacuum vessel 2.

When the flow rate of oxygen in supplying the second gas to the vacuum vessel 2 was set to 10 SCCM, the formation speed of an SiO₂ film was 75 nm/min. On the other hand, when the flow rate of oxygen in supplying the second gas to the vacuum vessel 2 was set to 35 SCCM, the formation speed was equal to or less than 1 nm/min. For reference, when the second gas is not mixed with oxygen, the film thickness distribution at the surface 100a of the substrate to be processed 100 depends on the flow of the second gas (mainly silicon oxide gas) supplied from the lower gas supply system 7. When the second gas is mixed with oxygen, the film thickness distribution at the surface 100a of the substrate to be processed 100 depends less on the flow silicon oxide gas.

When only special process gas as the second gas is used, in the vicinity of the second gas injection holes, these chemical compounds are used by surplusage, and the reason is because the deficiency of chemical compounds is easily caused in region separated from the second gas injection holes. When a mixed gas of tetra-ethoxy gas and oxygen was used as the second gas, the film thickness distribution of the formed insulating film (SiO₂ film) was improved by 20% as compared with a case where only tetra-ethoxy gas (silicon oxide gas) was used. That is, it was found that use of a mixed gas of tetra-ethoxy gas and oxygen as the second gas improved the uniformity of the insulating film (SiO₂ film).

As described above, the insulating film forming method of the embodiment comprises providing a substrate to be processed 100 in a vacuum vessel 2 with an electromagnetic wave incident face F which an electromagnetic wave enters, supplying a first gas to the vacuum vessel 2 from first gas injection holes in a first gas supply system 6, supplying gas including organic silicon compound gas and oxygen gas, such as a mixed gas of tetra-ethoxy silane gas and oxygen gas, from a second gas injection holes 52 in a second gas supply system 7 provided farther away from the electromagnetic wave incident face F than the first gas injection holes 42, causing the electromagnetic wave to enter the vacuum vessel 2 from the electromagnetic wave incident face F, thereby producing surface-wave plasma in the vacuum vessel 2 and depositing silicon oxide on the substrate to be processed.

In the insulating film forming method, the first gas can be supplied to a region where the plasma density is relatively high (a region where electrons are accelerated directly by the electric field caused by the electromagnetic wave), which enables oxygen radicals to be generated efficiently in the vacuum vessel 2. Moreover, the second gas including organic silicon compounds can be supplied to a region where electromagnetic waves are shielded by high-density plasma and therefore do not arrive. Therefore, the excessive decomposition of organic silicon compounds or organic metallic compounds as a result of the collision of electrons can be suppressed. Consequently, a high-quality insulating film (silicon oxide film) 101 which has less oxygen deficiency, good film quality, and excellent step coating properties can be formed on the substrate to be processed 100 almost without causing ion damage.

When organic metallic compound gas for metal oxide formation is used instead of organic silicon compound gas, an effect same as above advantageous effect is provided.

Furthermore, the inventors have found that use of the special process gas and diluted gas enabled the film thickness of the formed insulating film (silicon oxide film or metal-oxide film) to be made more uniform than when only the special process gas was used. The reason why the film thickness was uniformized is not clear. It is conceivable that organic silicon compound gas or organic metallic compound gas collides with diluted gas molecules, causing the organic silicon compound gas or organic metallic compound gas to spread (diffuse) widely all over the processing vessel.

Furthermore, in the plasma film forming apparatus 1a, the second gas injection holes 52 are made in the ring-shaped member (ring-shaped pipe) 51 formed so as to have a larger outer shape than the outer edge of the substrate to be processed 100. This makes oxygen radicals and the like produced near the first gas injection holes 42 less liable to be impeded by the second gas supply system 7. As a result, oxygen radicals and the like are allowed to reach the region to which the second gas is supplied (or injected), in the form of diffusion flux. Specifically, since organic silicon compounds and/or organic metallic compounds can be caused to react with oxygen radials efficiently in the region corresponding to the whole region of the substrate to be processed 100, it is possible to form an insulating film of more uniform film thickness on the substrate 100. it is desirable that the ring-shaped member 51a is formed so as to have a similar shape to the outer shape of the substrate to be processed. That is, in the embodiment, a square-ring shape of the ring-shaped member 51a is analogue of a square-ring shape of the square substrate to be processed 100. This makes it possible to supply the second gas to the region corresponding to the substrate 100 all over efficiently.

In addition, plurality of the waveguide slot antennas 10 arranged in same plane can radiate electromagnetic waves uniformly to a large-area region or a square (rectangular) region. Specifically, even when a large substrate or a square substrate (or rectangular substrate) is used as a substrate to be processed 100 (or when an insulating film is formed on a large substrate or a square substrate), the electromagnetic wave radiated from each the waveguide slot antennas 10 enter the vacuum vessel 2 from the electromagnetic wave incident face F in the plasma film forming apparatus 1a, which enables good uniform surface-wave plasma to be produced in the vacuum vessel 2. Therefore, from this respect, it possible to form an insulating film of good uniformity on a large substrate or a square substrate.

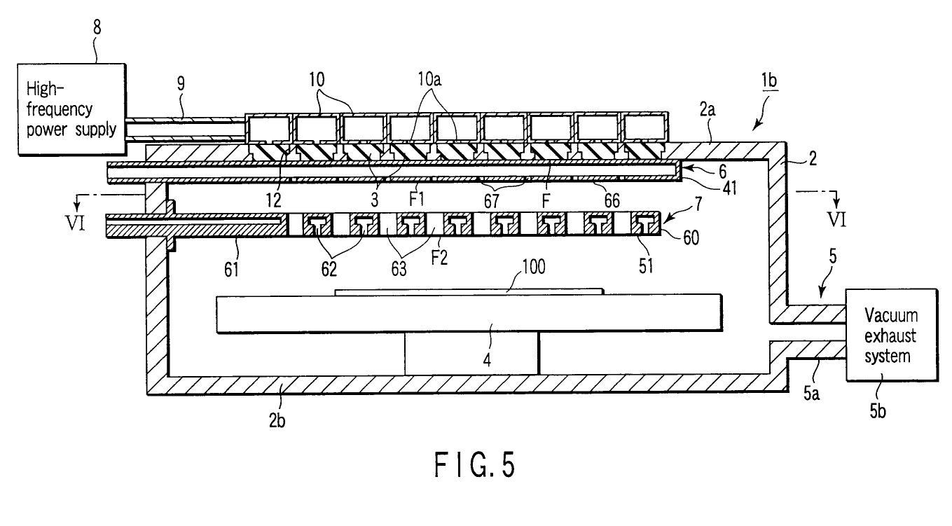

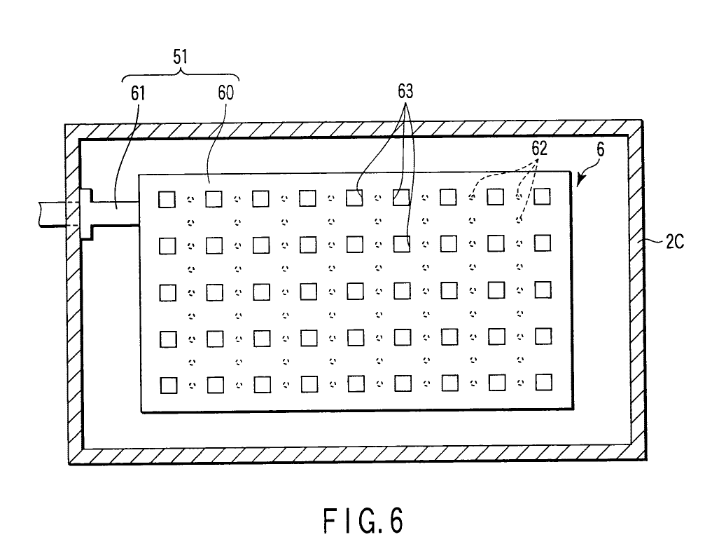

FIGS. 5 and 6 show a plasma film forming apparatus of the second embodiment. The plasma film forming apparatus 1b differs from the above-described plasma film forming apparatus 1a in the configuration of the upper gas supply system 6 and lower gas supply system 7. Since the remaining configuration of the plasma film forming apparatus 1b is the same as that of the plasma film forming apparatus 1a, the same parts are indicated by the same reference numeral and explanation of them will be omitted.

The upper gas introducing pipe 41 of the upper gas supply system 6 in the plasma film forming apparatus 1b has a square-flat-box-like shower plate 66. In the bottom wall of the shower plate 66, a large number of gas injection holes 67 are formed such as a matrix. One end part of the shower plate 66 becomes small in width, and extends outside the vacuum vessel 2 through the sidewall 2c of the vacuum vessel 23. The part of the shower plate 66 enables a first gas cylinder (not shown) in which the first gas is held to be provided detachably.

The lower gas introducing portion 51 of the lower gas supply system 7 in the plasma film forming apparatus 1b has a shower plate 60 and an extended pipe 61. The shower plate 60 has a pair of square-shaped plate materials (top wall and bottom wall) with predetermined space facing each other and a brim connecting the brims of these plate materials. The pair of the plate materials, which has a large number of square-shaped through-holes 63 arranged such as a matrix for allowing the first gas or oxygen radicals to flow from above to below the shower plate 60, is formed into a lattice shape. The lattice-shaped internal space of the shower plate 60, which is designed to allow the second gas to flow, is connected to the extended pipe 61. One end part of the extended pipe 61 extends outside the vacuum vessel 2 via the sidewall 2c of the vacuum vessel 2. To one end of the extended pipe 61, a second gas cylinder (not shown) in which the second gas is held can be provided detachably. The shower plate 60 is provided so as to cover the substrate support table 4 and the substrate to be processed 100 on the support table 4 from above. In the bottom wall of the shower plate 60, a plurality of second gas injection holes are made.

The shower plate 60 may be provided with heating means. For example, a high-temperature medium circulator including a pump, a circulation path, a heater, and high-temperature fluid may be used as the heating means. The high-temperature fluid may be air, gas, such as nitrogen gas, argon gas, krypton gas, or xenon gas, or liquid, such as water, ethylene glycol, mineral oil, alkylbenzene, diaryl alkane, tri-aryl dialkane, diphenyl-diphenyl ether mixture, alkyl biphenyl, or alkyl naphthalene. The circulation path for circulating the high-temperature fluid (high-temperature gas or high-temperature fluid) may be provided in the shower plate 60.

As described above, heating the lower gas supply system 7 by the circulation of the high-temperature medium makes it possible not only to transmit heat energy to the lower gas supply system rapidly but also to heat the lower gas supply system 7 uniformly. Therefore, when an insulating film is formed using gas including organic silicon compound gas or organic metallic compound gas, it is possible to prevent fluctuations in the amount of gas supply caused by the liquefaction of organic silicon compound gas or organic metallic compound gas.

Using the plasma film forming apparatus 1b makes it possible to form an insulating film which has less ion damage and is superior in film thickness uniformity.

Furthermore, in the insulating film forming method, since a mixed gas including at least one of organic silicon compound gas and organic metallic compound gas and at least one of oxygen gas and diluted gas is used as the second gas, an insulating film (silicon oxide film or metal-oxide film) can be made more uniform than when only organic silicon compound gas or only organic metallic compound gas is used as the second gas. Therefore, even when the plasma film forming apparatus 1b is used which includes the shower plate 60 where it is relatively difficult to distribute the second gas injection holes 62 in the second gas supply system 7 all over the object to be processed, an insulating film excellent in film-thickness uniformity can be formed on the substrate 100 to be processed.

A plasma film forming apparatus used to realize the insulating film forming method of the embodiment is not limited to the above-described plasma film forming apparatuses 1a, 1b. For instance, the dielectric widows may be provided inside the vacuum vessel. In that case, the upper gas supply system may be formed in the dielectric windows. Specifically, the upper gas supply may include a gas flow path which allows the first gas to flow, a plurality of connecting paths which connect the gas flow path to the inside of the vacuum vessel, and a connecting tube which connects the gas flow path to the outside of the vacuum vessel. The gas flow path and connecting paths can be formed by, for example, cutting the dielectric windows. In this case, the gas flow path and connecting tube constitute a first gas introducing portion (upper gas introducing portion). The opening end of a connecting path makes a first gas injection hole which supplies the first gas to the vacuum vessel 2. The connecting tube may be integral with or separate from the dielectric windows. In this case, too, the inside face of each dielectric window functions as an electromagnetic wave incident face F.

In the insulating film forming method of the embodiment, since the vacuum vessel is evacuated to a vacuum temporarily and then the first and second gases are supplied to the vacuum vessel, the gas pressure difference between almost atmospheric pressure and a pressure almost close to vacuum, that is, a gas pressure difference of about 1 kg/cm², is applied to the vacuum vessel. It is relatively easy to form the body of the vacuum vessel made of metal material or the like so as to have such a strength as withstands the gas pressure difference. However, to form the dielectric windows made of synthetic quartz or the like so as to have such a strength as withstands the gas pressure difference requires the windows to be made thicker.

In contrast, in the plasma film forming apparatus which has the dielectric windows provided inside the vacuum vessel, the gas pressure difference between almost atmospheric pressure and a pressure almost close to vacuum, that is, a gas pressure difference of about 1 kg/cm², is not applied to the vacuum vessel. As a result, it is possible to make the dielectric windows relatively thin, which is suitable for a case where an insulating film is formed on a substrate as large as 1 by 1 meters square.

The first gas is not restricted to such rare gas as krypton gas. For instance, gas including at least one of oxygen gas and rare gas may be used. When a mixed gas of oxygen gas and rare gas (helium, neon, argon, krypton, or xenon) is used, their mixing ratio is arbitrary. The insulating film forming speed can be changed according to the additive rate of rare gas.

Since in most of organic silicon compounds and organic metallic compounds, their elements include oxygen (oxygen atoms), oxygen gas is not necessarily included in the first gas. The first gas is caused to include rare gas, thereby producing oxygen radicals in the vacuum vessel 2, which enables an insulating film 101 of good uniformity on the substrate to be processed 100. Since causing the first gas to include rare gas enables the plasma density to increase, which improves the film forming speed.

On the other hand, causing the first gas to include oxygen gas enables more oxygen radicals to be produced in the vacuum vessel 2. Therefore, it is possible to form on the substrate 100 an insulating film which is excellent in uniformity and has a good film quality with less oxygen damage.

When the first gas includes oxygen gas, the first gas is supplied to the vacuum vessel 2 from the first gas injection holes 42 made in positions where the distance from the electromagnetic wave incident face F is smaller than the skin depth of surface-wave plasma. This causes the oxygen gas to be decomposed efficiently near the electromagnetic wave incident face F, thereby producing oxygen radicals efficiently. Moreover, the resulting oxygen radicals can be caused to react with the second gas supplied from the second gas injection holes 52 sufficiently. Therefore, it is possible to form, at a good film forming speed, an insulating film which is excellent in film-thickness uniformity and has a film quality superior in step coating properties.

Furthermore, when the first gas includes oxygen gas, it is desirable that the flow rate in supplying oxygen gas to the vacuum vessel 2 should be set larger than the flow rate in supplying the second gas to the vacuum vessel 2. This enables more oxygen radicals to exist in the region to which the second gas is supplied than the second gas. Consequently, since the oxidation of the silicon atoms in the organic silicon compound or the metal atoms in the organic metallic compound is enhanced, it is possible to form a high-quality insulating film (oxide film) with less oxygen deficiency.

As the second gas, gas including at least one of organic silicon compound gas and organic metallic compound gas and at least one of oxygen gas and diluted gas may be used. This makes it possible to from an insulating film 101 superior in film-thickness uniformity on the substrate to be processed 100, while suppressing damage done to the substrate 100 and the insulating film 101 formed on the substrate 100.

Furthermore, when the second gas includes organic silicon compound gas, tetra-ethoxy silane, tetra-alkoxy silane, vinyl alkoxy silane, alkyl tri-alkoxy silane, phenyl tri-alkoxy silane, polymethyl disiloxane, or polymethyl cyclo tetra-siloxane may be used as the organic silicon compound. This makes it possible to form a silicon oxide film of good film quality on the substrate to be processed 100.

When the second gas includes organic metallic compound gas, tri-methyl aluminum, tri-ethyl aluminum, tetra-propoxy zirconium, penta-ethoxy tantalum, or tetra-propoxy hafnium may be used as the organic metallic compound. Selecting tri-methyl aluminum or tri-ethyl aluminum enables an aluminum oxide film to be formed on the substrate to be processed 100. Selecting tetra-propoxy zirconium enables a zirconium oxide film to be formed on the substrate 100. Selecting penta-ethoxy tantalum enables a tantalum oxide film to be formed on the substrate 100. Selecting tetra-propoxy hafnium enables a hafnium oxide film to be formed on the substrate 100. Hafnium oxide and zirconium oxide have higher permittivity than that of silicon oxide. Therefore, selecting tetra-propoxy hafnium or tetra-propoxy zirconium makes it possible to form an insulating film 101 which has better electric insulation than a silicon oxide film.

While the organic silicon compound may be, for example, tetra-ethoxy silane, tetra-alkoxy silane, vinyl alkoxy silane, alkyl tri-alkoxy silane, phenyl tri-alkoxy silane, polymethyl disiloxane, or polymethyl cyclo tetra-siloxane as described above, it is not limited to these. While the organic metallic compound may be, for example, tri-methyl aluminum, tri-ethyl aluminum, tetra-propoxy zirconium, penta-ethoxy tantalum, and tetra-propoxy hafnium, it is not limited to these.

When the second gas includes diluted gas, it is desirable that the diluted gas should include at least one of helium gas, neon gas, argon gas, krypton gas, and xenon gas, that is, rare gas. Helium gas, neon gas, argon gas, krypton gas, and xenon gas do not react with organic silicon compounds and organic metallic compounds. Therefore, they can dilute the second gas without affecting the decomposing process of organic silicon compounds or organic metallic compounds.

As the substrate to be processed 100 (a material to be processed), for example, a glass substrate, such as quartz glass, a ceramic substrate, a resin substrate, or a silicon substrate, such as a semiconductor wafer, may be used. Moreover, on the substrate 100, a semiconductor layer of single-crystal silicon, polycrystalline silicon formed by laser crystallization or solid-phase crystallization, microcrystalline silicon, or amorphous silicon may be formed. Furthermore, on the substrate 100, semiconductor layers and insulating films may be stacked one on top of another in random order. In addition, on the substrate 100, a circuit element or a part of a circuit element may be formed which is constructed by staking semiconductor layers and insulating films one on top of another in random order.

In the insulating film forming method of this invention, it doesn't matter in what order the supply of the first gas to the processing vessel, the supply of the second gas to the processing vessel, and the supply of the electromagnetic wave to the processing vessel are executed. When the first gas or second gas includes two or more types of compound gas, these may be supplied to the processing vessel in the form of a mixed gas or be introduced separately into the vessel.

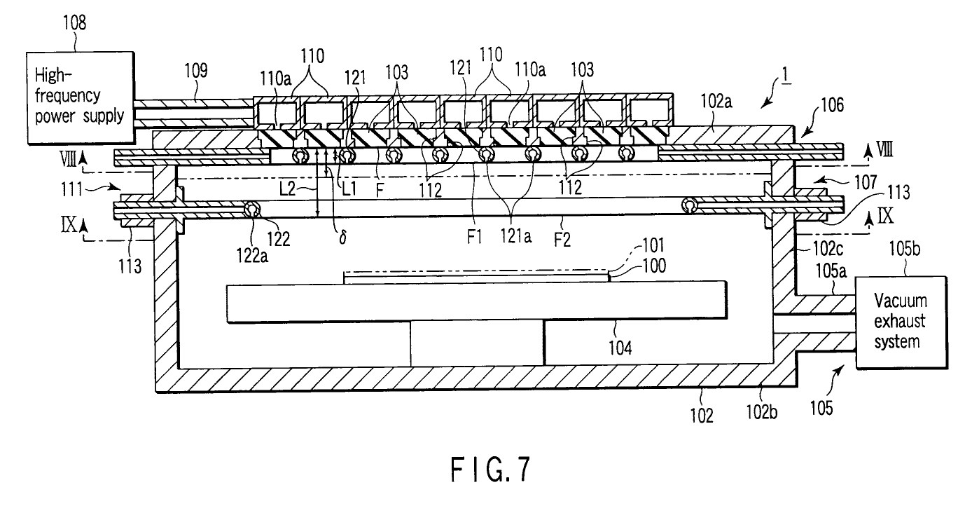

Hereinafter, referring to FIGS. 7 to 9, a first embodiment of the present invention will be explained. In this embodiment, an embodiment of an insulating film forming method of the present invention and an embodiment of an insulating film forming apparatus of the present invention will be explained.

FIG. 7 shows an example of an insulating film forming apparatus. The insulating film forming apparatus 1 of the embodiment comprises a vacuum vessel 102 as a processing vessel, one or more dielectric members 103, for example, nine dielectric members, a substrate support table 104, a gas exhaust system 105, a gas exhaust section 105a, a vacuum exhaust system 105b, an upper gas supply system 106 as a first gas supply system, a lower gas supply system 107 as a second gas supply system, a high-frequency power supply 108, a waveguide 109, one or more waveguide slot antennas 110, for example, nine waveguide slot antennas, and heating means 111. The vacuum vessel 102, the dielectric members 103, the substrate support table 104, the gas exhaust system 105, the gas exhaust section 105a, the vacuum exhaust system 105b, the upper gas supply system 106, the lower gas supply system 107, the high-frequency power supply 108, the waveguide 109, and the waveguide slot antennas 110 comprised by the insulating film forming apparatus 1 of the embodiment are corresponding to the vacuum vessel 2, the dielectric windows 3, the substrate support table 4, the gas exhaust system 5, the gas exhaust section 5a, the vacuum exhaust system 5b, the upper gas supply system 6, the lower gas supply system 7, the electromagnetic wave source 8, the electromagnetic wave supply waveguide 9, and the waveguide slot antennas 10 comprised by the plasma film forming apparatus 1a of first embodiment, respectively.

As a material for forming the top cover 2a, bottom wall 2b, and sidewall 2c, the material which is hermetic and emits no gas, such as glass, or metal material, such as aluminum, may be used.

As a materials for forming the dielectric members 103, a material for transmitting electromagnetic waves, such as synthetic quartz or aluminum oxide, may be used. Hereinafter, the dielectric members are also referred to as the dielectric windows 103.

The upper gas supply system 106 is for introducing a first gas including at least one of rare gas and oxygen gas into the vacuum vessel 102. In the insulating film forming apparatus of the embodiment, the upper gas introducing portion 106 has, for example, an upper gas introducing pipe 121 as a first gas introducing portion.

The upper gas introducing pipe 121 is made of metal, such as aluminum, stainless steel, or titanium, or dielectric, such as silicon oxide, aluminum oxide, or aluminum nitride. When the effect of the upper gas introducing pipe 121 on electromagnetic fields and plasma is taken into consideration, it is desirable that the upper gas introducing pipe 121 should be made of dielectric material. However, taking the process of forming a pipe into account, it is inexpensive and easy to make the upper gas introducing pipe 121 of metal material. Therefore, when the upper gas introducing pipe 121 is made of metal material, an insulating film should be formed on the outside face of the upper gas introducing pipe 121.

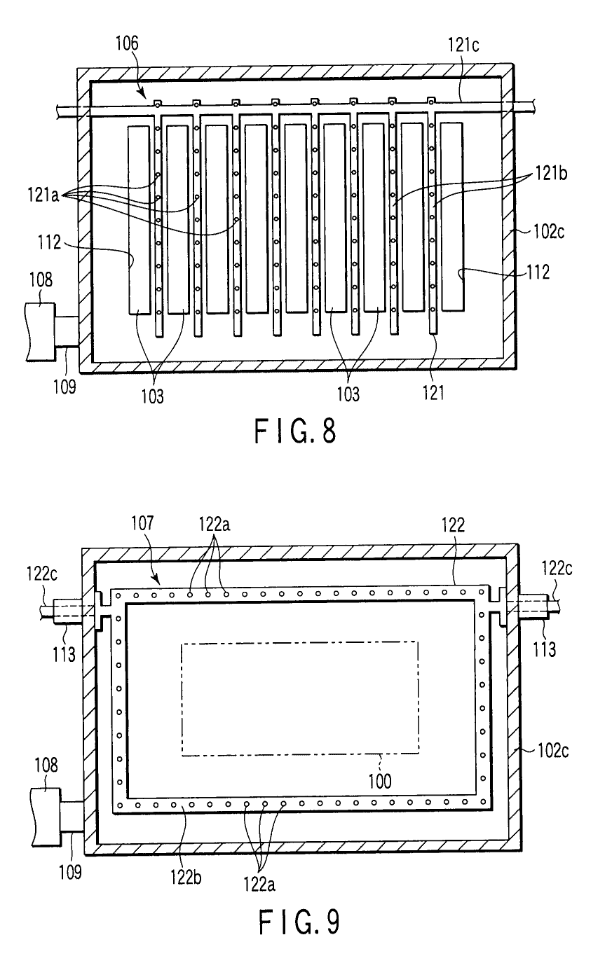

As shown in FIG. 8, the upper gas introducing pipe 121 is provided along the inside face of the top wall 102a (beam) in the vacuum vessel 102, keeping away from the regions where the dielectric windows 103 are formed. Specifically, the upper gas introducing pipe 121 has a plurality of pipe sections 121b and an extended section 121c. The plurality of pipe sections 121b are laid in parallel with one another so as to run along the inside face of the top wall 102a (beam) of the vacuum vessel 102. The extended section 121c is laid so as to be at right angles with the pipe sections 121b and connects these pipe sections 121b to one another. Both ends of the extended section 121c extend outside the vacuum vessel 102 via the sidewall 102c of the vacuum vessel 102. To both or one end of the extended section 121c, a first gas cylinder (not shown) in which the first gas is held can be provided detachably.

In each of the pipe sections 121b, there are provided a plurality of gas injection holes 121a at almost regular intervals in the longitudinal direction. Therefore, the gas injection holes 121 are positioned almost in the same plane. These gas injection holes 121a are provided in positions where the distance L1 from the electromagnetic wave incident face F is smaller than the skin depth δ of surface-wave plasma. In the embodiment, the upper gas introducing pipe 121 is so formed that the distance L1 between a virtual plane F1 in which the gas injection holes 121a are made and the electromagnetic wave incident face F is less than 10 mm, for example, 3 mm. Laying the upper gas introducing pipe 121 causes the gas injection holes 121a to be provided 3 mm below the electromagnetic wave incident face F (see FIG. 7).

The lower gas supply system 107 is for introducing a second gas including organic silicon compounds or organic metallic compounds into the vacuum vessel 102. In the insulating film forming apparatus 1 of the embodiment, the lower gas supply system has, for example, a lower gas introducing pipe 122 as a second gas introducing portion.

Like the upper gas introducing portion, the lower gas introducing pipe 122 is made of metal, such as aluminum, stainless steel, or titanium, or dielectric, such as silicon oxide, aluminum oxide, or aluminum nitride. In a transient state during the time elapsed until plasma at the beginning of discharge reaches a surface-wave plasma state, electromagnetic waves also reach the lower gas supply system 107. Therefore, if the lower gas introducing pipe 122 is made of metal material, the lower gas supply system 107 might have an effect on electromagnetic fields and plasma in the transient state. For this reason, when the effect of the lower gas introducing pipe 122 on electromagnetic waves and plasma is considered, it is desirable that the lower gas introducing pipe 122 should be made of dielectric material. When the lower gas introducing pipe 122 is made of metal material, it is desirable that an insulating film should be formed on the outside face of the lower gas introducing pipe 122.

As shown in FIG. 9, the lower gas introducing pipe 122 has a ring-shaped section 122b and a pair of extended sections 122c. The ring-shaped section 122b is formed so as to be slightly larger than the outer edge of the substrate to be processed 100. Each of the extended sections is connected to the ring-shaped section 122b. One end of each of the extended sections 122c extends outside the vacuum vessel 102 via the sidewall 102c of the vacuum vessel 102. A second gas cylinder (not shown) in which the second gas is held can be provided detachably to one end of at least one of the extended sections 122c.

In the ring-shaped section 122b, a plurality of gas injection holes 122a are made at almost regular intervals in the longitudinal direction. These gas injection holes 122a are provided in positions where the distance L2 from the electromagnetic wave incident face F is larger than the skin depth δ of the surface-wave plasma. In the embodiment, the lower gas introducing pipe 122 is so formed that the distance L2 between a virtual plane F2 in which the gas injection holes 122a are made and the electromagnetic wave incident face F is 10 mm or more, for example, 30 mm. Laying the lower gas introducing pipe 122 causes the gas injection holes 122a to be provided 30 mm below the electromagnetic wave incident face F (see FIG. 7).

Since the organic silicon compound gas or organic metallic compound gas included in the second gas has a higher boiling point than monosilane, it is liable to liquefy. Therefore, to introduce the second gas into the vacuum vessel 102 stably, it is desirable that the lower gas supply system 107 should be kept at suitable temperature, that is, about 80° C. to 200° C. For this reason, in the insulating film forming apparatus 1 of the embodiment, the lower gas supply system 107 is provided with heating means 111. The heating means 111 includes, for example, a heater 111.

Specifically, the heater 113 is provided on, for example, the outer surface of each of the extended sections 122c of the lower gas introducing pipe 122. This enables heat to be transmitted to all of the lower gas supply system 107 by the heat conduction of the materials constituting the lower gas introducing pipe 122. Therefore, the lower gas supply system 107 can be kept at a suitable temperature with the simpler configuration than when the heating means 111 is provided inside the vacuum vessel 102. When heat is transmitted to all of the lower gas supply system 107 by the heat conduction of the materials constituting the lower gas introducing pipe 122, it is desirable that the lower gas introducing pipe 122 should be made of a material whose heat conduction coefficient is large, such as aluminum nitride.

Next, an insulating film forming method using the insulating film forming apparatus 1 will be explained. In the embodiment, explanation will be given about a case where an insulating film 101 is formed on a substrate to be processed 100 by using oxygen gas as the first gas and tetra-ethoxy silane, a kind of tetra-alkoxy silane, as the second gas.

A substrate to be processed 100 is placed on the substrate support table 4. The gas exhaust system 105 is driven, evacuating the vacuum vessel 102 practically to a vacuum. The upper gas supply system 106 supplies oxygen gas to the vacuum vessel 102 at a flow rate of 400 SCCM so that the gas pressure in the vacuum vessel may become 80 Pa. At the same time, the lower gas supply system 107 supplies tetra-ethoxy silane gas to the vacuum vessel 102 at a flow rate of 12 SCCM. At this time, the heating means 111 keeps the lower gas supply system 107 at a suitable temperature (in the range of about 80° C. to 200° C.)

The high-frequency power supply 108 is turned on. As a result, a 2.45-GHz electromagnetic wave is directed to the waveguide slot antennas 110 via the waveguide 109. The electromagnetic wave is radiated from the waveguide slot antennas 110 toward the dielectric windows 103 with a power density of 3 W/cm².

The 2.45-GHz electromagnetic wave is caused to enter the vacuum vessel 102 via the dielectric windows 103. As a result, the oxygen gas is excited, producing plasma, with the result that the electron density in the plasma near the electromagnetic wave incident face F increases. As the electron density in the plasma near the electromagnetic wave incident face F increases, this makes it difficult for the electromagnetic wave to propagate in the plasma, with the result that the electromagnetic wave attenuates. Accordingly, the electromagnetic wave does not reach a region separate from the electromagnetic wave incident face F. That is, surface-wave plasma appears. Since the oxygen gas is introduced into the vacuum vessel 102 from a position whose distance L1 from the electromagnetic wave incident face F is 3 mm, that is, from a region whose distance L1 from the electromagnetic wave incident face F is smaller than the skin depth δ, oxygen molecules are excited by high-density plasma in a state where surface-wave plasma is being produced, which produces oxygen radicals efficiently.

On the other hand, tetra-ethoxy silane gas is introduced into the vacuum vessel 102 from a position whose distance L2 from the electromagnetic wave incident face F is 30 mm, that is, from a region whose distance L2 from the electromagnetic wave incident face F is larger than the skin depth. Therefore, since the electromagnetic wave is shielded by high-density plasma and does not reach the region in the vacuum vessel 102 into which tetra-ethoxy silane gas has been introduced, the excessive decomposition of tetra-ethoxy silane gas by the electromagnetic wave can be suppressed. Moreover, even in a position whose distance from the electromagnetic wave incident face F is 30 mm, oxygen radicals arrive in the form of diffusion flux, causing tetra-ethoxy silane and oxygen radicals to react with one another efficiently, which enhances the decomposition of tetra-ethoxy silane. As a result, on the surface of the substrate to be processed 100, silicon oxide deposits. Since tetra-ethoxy silane is a compound whose molecular volume is larger than that of monosilane, tetra-ethoxy silane adheres to the surface of the substrate 100 in a relatively uniform manner, while migrating over the substrate by its three-dimensional effect. Consequently, an insulating film (silicon oxide film) 101 of good film quality is formed on the substrate 100.

Under such conditions, the insulating film 101 was formed on the substrate 100 at a forming speed of 29 nm/min. The formed insulating film 101 had a leakage current of 2×10⁻¹⁰ A/cm² when an electric field of 2 MV/cm was applied and had a fixed charge density of 2×10⁻¹¹/cm² or less. From these results, it is seen that the insulating film forming method of the embodiment enables both of the leakage current and fixed charge density to be suppressed low and achieves a good forming speed of the insulating film 101.

FIG. 18 shows the relationship between the electron temperature in surface-wave plasma and the distance from the electromagnetic wave incident face F. Conceivably, the reason why the electron temperature drops sharply where the distance from the electromagnetic wave incident face F is about 10 mm is that the electron temperature in the region where the electromagnetic wave arrives and directly excites electrons (that is, the region in the skin depth δ) differs the electron temperature in the region where electrons are hardly excited (that is, the region off the skin depth δ). From the result, it is seen that the skin depth δ is about 10 mm at a maximum under the condition where surface-wave plasma is maintained.

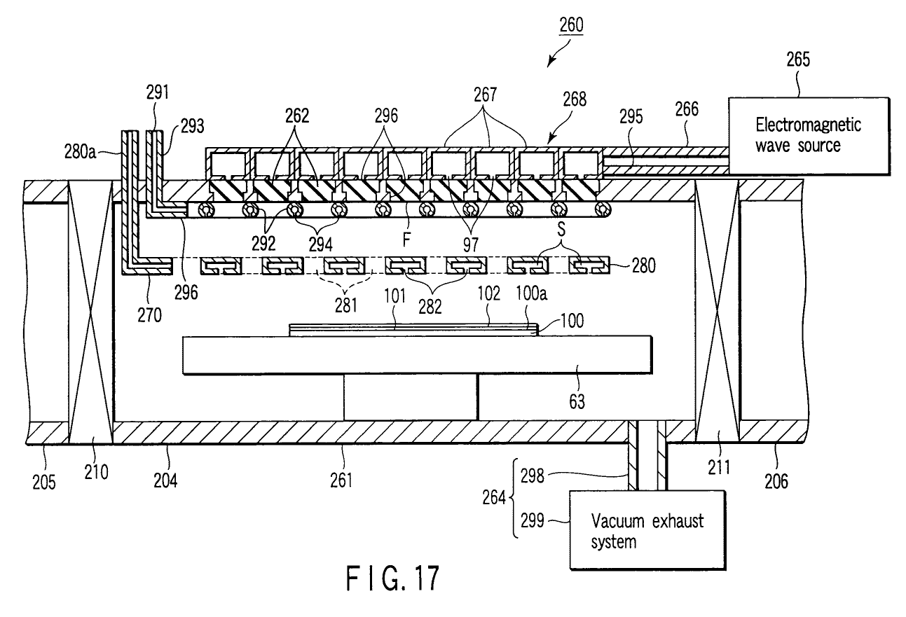

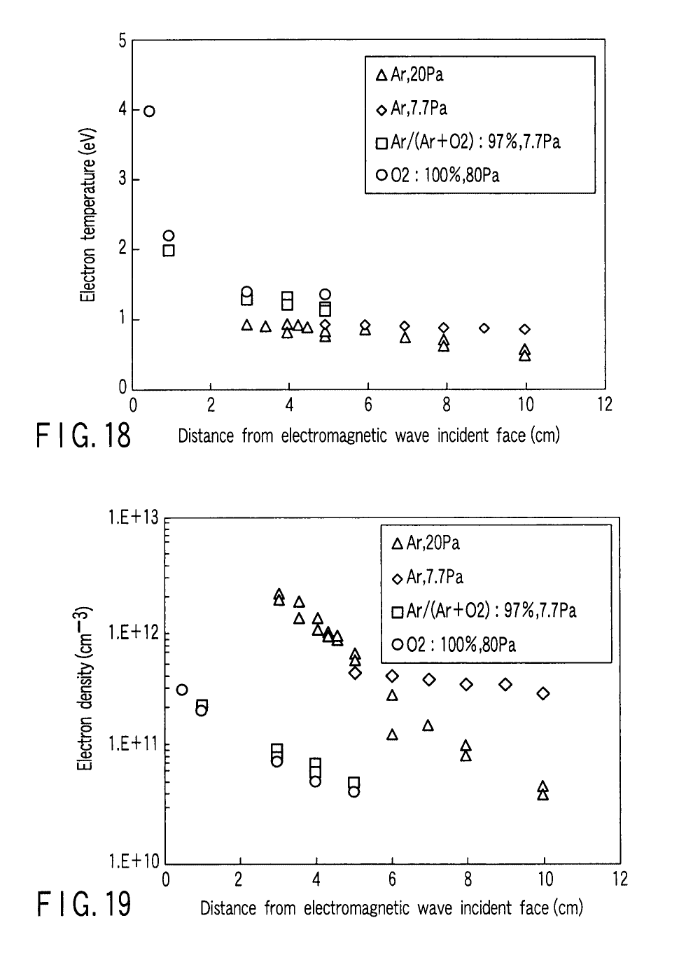

FIG. 17 shows the relationship between the electron density in surface-wave plasma and the distance from the electromagnetic wave incident face F. Since a region excited by the electromagnetic wave is localized in surface-wave plasma as described above, the electron density decreases as the distance from the electromagnetic wave incident face F increases. Therefore, it was found that the electron density in a position about 10 mm away from the electromagnetic wave incident face F was 50% or less of the electron density at the electromagnetic wave incident face F. From this result, it is seen that, since oxygen takes in electrons easily, mixing oxygen caused the electron density to decrease as compared with a case where plasma was produced using 100% argon.

As described above, the insulating film forming method of the present invention comprises a step of providing the substrate to be processed 100 in the vacuum vessel 102 with the electromagnetic wave incident face F which electromagnetic waves enter, a step of not only introducing oxygen gas as a first gas including at least one of rare gas and oxygen gas into the vacuum vessel 102 from a position whose distance L1 from the electromagnetic wave incident face F is less than 10 mm but also introducing, separately from the first gas, a second gas including tetra-ethoxy silane gas as organic silicon compound gas into the vacuum vessel 102 from a position whose distance L2 from the electromagnetic wave incident face F is 10 mm or more, and a step of depositing silicon oxide on the substrate 100 by causing the electromagnetic wave to enter the vacuum vessel 102 from the electromagnetic wave incident face F to produce surface-wave plasma using the first and second gases in the vacuum vessel 102. Therefore, it is possible to form a good insulating film 101 on the substrate 100, while suppressing damage done to the substrate 100 and the insulating film 101 formed on the substrate 100.

While in the insulating film forming method of the embodiment, oxygen gas and tetra-ethoxy silane gas have been used as the first gas and the second gas respectively, the present invention is not limited to this.

The first gas is not restricted to oxygen gas and may be a gas containing at least one of rare gas and oxygen gas. For example, a mixed gas of oxygen gas and one or more deluded gases of helium gas, neon gas, argon gas, krypton gas, and xenon gas may be used as the first gas. Helium gas, neon gas, argon gas, krypton gas, or xenon gas may be added to oxygen at an additive rate ranging from 10% to 99%. According to the additive rate, the insulating film forming speed can be increased.

Furthermore, when a gas including oxygen gas is used as the first gas, the flow rate in supplying oxygen gas to the vacuum vessel 102 is set larger than the flow rate in supplying the second gas to the vacuum vessel 102, enhancing the oxidation of silicon atoms in the organic silicon compound or metal atoms in the organic metallic compound, which makes it possible to form a high-quality oxide film with less oxygen deficiency.

As the second gas, a gas including an organic silicon compound or a organic metallic compound may be used. This makes it possible to form a good insulating film on the substrate 100, while suppressing damage caused to the substrate 100 and the insulating film formed on the substrate 100.

While the organic silicon compound may be, for example, tetra-alkoxy silane, vinyl alkoxy silane, alkyl tri-alkoxy silane, phenyl tri-alkoxy silane, polymethyl disiloxane, or polymethyl cyclo tetra-siloxane, the present invention is not limited to this. While the organic metallic compound may be, for example, tri-methyl aluminum, tri-ethyl aluminum, tetra-propoxy zirconium, penta-ethoxy tantalum, or tetra-propoxy hafnium, the present invention is not limited to this.

Furthermore, the insulating film forming apparatus 1 of the embodiment comprises the vacuum vessel 102 in which the substrate to be processed 100 can be provided, the high-frequency power supply 108 for generating electromagnetic waves, antennas which radiate electromagnetic waves toward the vacuum vessel 102, the dielectric windows 103 which have the electromagnetic wave incident face F on their inside face, are provided in the vacuum vessel 102 so as to constitute a part of the wall of the vacuum vessel 102, and transmit the electromagnetic wave radiated from the antennas to the inside of the vacuum vessel, the upper gas supply system 106 which has the upper gas introducing pipe 121 for introducing oxygen gas as the first gas including at least one of rare gas and oxygen gas into the vacuum vessel 102 and is provided to the vacuum vessel 102, and the lower gas supply system 107 which has the lower gas introducing pipe 122 for introducing the second gas including an organic silicon compound or an organic metallic compound into the vacuum vessel 102 and is provided to the vacuum vessel 102. The upper gas introducing pipe 121 is provided closer to the electromagnetic wave incident face F than the lower gas introducing pipe 122. The distance L2 between the gas injection hole 122a of the lower gas introducing pipe 122 and the electromagnetic wave incident face F is set to 10 mm or more. Use of this insulating film forming apparatus 1 makes it possible to form a good insulating film on the substrate 100, while suppressing damage done to the substrate 100 and the insulating film formed on the substrate 100.

In addition, since the insulating film forming apparatus 1 of the embodiment has one or more waveguide slot antennas 110, it has less dielectric loss and withstands a large amount of power. Moreover, since the waveguide slot antennas 110 are arrange side by side and caused to face the outer surfaces of the dielectric windows 103 in a one-to-one correspondence, an insulating film can be made even for a square substrate with a large area for use with a large liquid-crystal display device or the like.

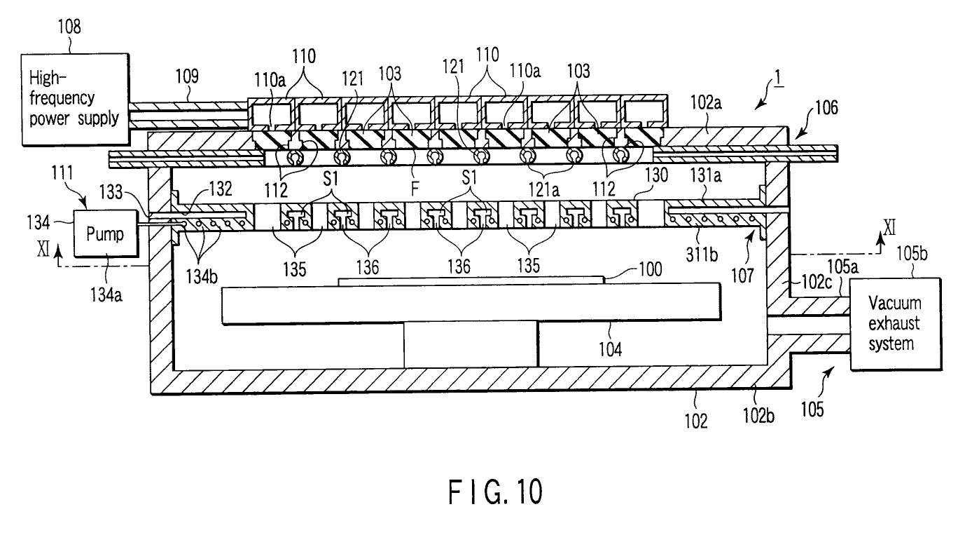

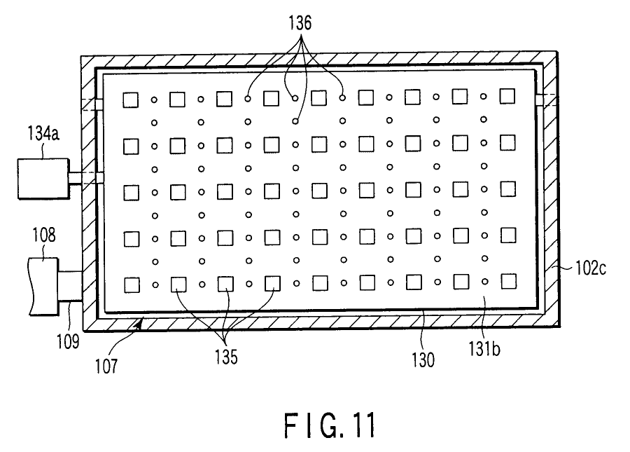

Hereinafter, referring to FIGS. 10 and 11, an insulating film forming apparatus according to a second embodiment of the present invention will be explained.

The insulating film forming apparatus of the second embodiment differs from the insulating film forming apparatus of the first embodiment in the lower gas supply system 107 and heating means 111. Since the remaining configuration is the same as that of the first embodiment, the same parts are indicated by the same reference numerals and repetitive explanation will be omitted.

The lower gas supply system 107 is made of metal, such as aluminum, stainless steel, or titanium, or dielectric, such as silicon oxide, aluminum oxide, or aluminum nitride. As described in the first embodiment, it is desirable that dielectric should be used as a material for the lower gas supply system 7.

The lower gas supply system 107 has a shower plate 130 as a first gas introducing portion (lower gas introducing portion). As shown in FIG. 10, the shower plate 130 is formed into a flat-box shape having a pair of plate materials 131a, 131b facing each other in such a manner that the second gas is allowed to flow in an internal space S1. The shower plate 130 has an openings 132 for opening the internal space S1. Moreover, in the sidewall 102c of the vacuum vessel 102, openings 133 for opening the internal space S1 to the outside of the vacuum vessel 102 is made. Therefore, the internal space S1 of the shower plate 130 is opened to the outside of the vacuum vessel 102 via the walls of the openings 132 and openings 133. The second gas is introduced into the internal space S1 of the shower plate 130 via the openings 133 and openings 132. The shower plate 130 is formed so as to be large enough to divide the vacuum vessel 102 into an upper chamber and a lower chamber in such a manner it covers the substrate support table 4 from above.

As shown in FIG. 11, in the shower plate 130, a large number of through-holes are made to allow the first gas or oxygen radicals to flow from the top chamber to the bottom chamber or vice versa. Moreover, in the shower plate 130, a large number of gas injection holes 136 are made in the lower plate material 131b.

Furthermore, the shower plate 130 is provided with heating means 111. The heating means 111 has a high-temperature medium circulator 134. The high-temperature medium circulator 134 includes a pump 134a, a circulation path 134b, a heater (not shown), and high-temperature fluid. The high-temperature fluid may be, for example, air, gas, such as nitrogen gas, argon gas, krypton gas, or xenon gas, or liquid, such as water, ethylene glycol, mineral oil, alkylbenzene, diaryl alkane, tri-aryl dialkane, diphenyl-diphenyl ether mixture, alkyl biphenyl, or alkyl naphthalene.

The circulation path 134b for circulating the high-temperature fluid (high-temperature gas or high-temperature fluid) is provided in the shower plate 130. The circulation path is isolated from the internal space allowing the first gas to flow. In the high-temperature medium circulator 134, the high-temperature fluid is heated by the heater and the pump 134a is operated to cause the high-temperature fluid to flow in the shower plate 130, which keeps the lower gas supply system 107 at a temperature in the range of about 80° C. to 200° C.

Heating the lower gas supply system 107 by the circulation of high-temperature medium in this way enables not only heat energy to be transmitted quickly to the lower gas supply system 107 but also the lower gas supply system 107 to be heated uniformly. Therefore, when an insulating film is formed using organic silicon compound gas or organic metallic compound gas, it is possible to suppress fluctuations in the amount of gas supply caused by the liquefaction of organic silicon compound gas or organic metallic compound gas.

As described above, use of the insulating film forming apparatus 1 makes it possible to suppress fluctuations in the amount of gas supply caused by the liquefaction of organic silicon compound gas or organic metallic compound gas. Therefore, when an insulating film 101 is formed on the substrate to be processed 100, good film-thickness controllability and film-thickness uniformity can be realized.

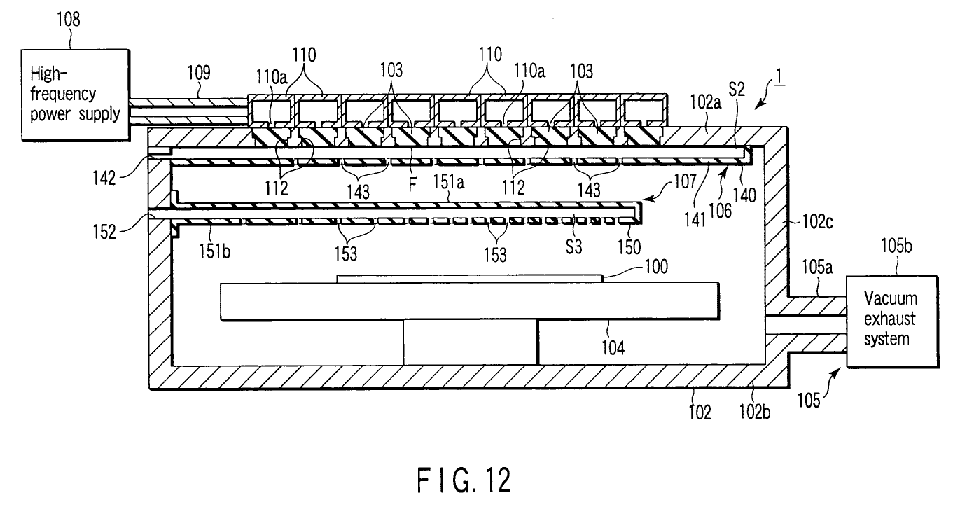

Hereinafter, referring to FIG. 12, an insulating film forming apparatus according to a third embodiment of the present invention will be explained.

The insulating film forming apparatus of the third embodiment differs from the insulating film forming apparatus of the first embodiment in the upper gas supply system 106 and lower gas supply system 107. Since the remaining configuration is the same as that of the first embodiment, the same parts are indicated by the same reference numerals and repetitive explanation will be omitted.

The upper gas supply system 106 and lower gas supply system 107 are made of metal, such as aluminum, stainless steel, or titanium, or dielectric, such as silicon oxide, aluminum oxide, or aluminum nitride. As described in the first embodiment, it is desirable that dielectric should be used as a material for the upper gas supply system 106 and lower gas supply system 7.

The upper gas supply system 106 has an upper shower plate 140 as a first gas introducing portion (upper gas introducing portion). The upper shower plate 140 has a plate material 141 which covers the inside face of the top wall 102a of the vacuum vessel 102 in such a manner that the first gas is allowed to flow in an internal space S2 between the top wall 102a of the vacuum vessel 102 and the plate material 141. The plate material is connected to the top wall 102a of the vacuum vessel 102 so as to keep the internal space S2 hermetic. The internal space S2 in the upper shower plate 140 is opened outside the vacuum vessel 102 via an opening 142 made in the sidewall 102c of the vacuum vessel 102. Through the opening 142, the first gas is introduced into the internal space S2 in the upper shower plate 140. In the plate material 141 of the upper shower plate 140, a large number of gas injection holes 143 are made at almost regular intervals.

In the upper shower plate 140, the plate material 141 made of metal, such as aluminum, stainless steel, or titanium is grounded to the top wall 102a of the vacuum vessel 102 and the gas injection holes are made sufficiently small, which enables plasma to be confined within the internal space S2. This makes it possible not only to suppress the arrival of plasma to the substrate 100 in a transient state during the time elapsed until plasma at the beginning of discharge reaches a surface-wave plasma state but also to block off high-energy ultraviolet rays included in plasma radiant light with the upper shower plate 140. Therefore, the effect of suppressing damage to the substrate 100 can be increased.

When the upper shower plate 140 is made of dielectric, such as silicon oxide, aluminum oxide, or aluminum nitride, plasma may be produced above or below the plate material 141, depending on the shape of the upper shower plate 140 or the gas pressure or the like in the internal space S2 of the upper shower plate 140.

When setting is done so as to cause plasma to be produced above the plate material 141, high-energy ultraviolet rays included in plasma radiant light is blocked off with the upper shower plate 140, which increases the effect of suppressing damage to the substrate 100.

When setting is done so as to cause plasma to be produced below the plate material 141, the first gas can be supplied to plasma in a distributed manner via the upper shower plate 140, which increases the uniformity of plasma. Here, when setting is done so as to cause plasma to be produced below the plate material 141, the electromagnetic wave incident face F is the interface (the undersurface of the plate material 141) between the plate material 141 and the internal space of the vacuum vessel 102. In other cases, the electromagnetic wave incident face F is the interface (the inside face of the dielectric windows 103) between the dielectric windows 103 and the internal space of the vacuum vessel 102.

The lower gas supply system 107 has a lower shower plate 150 as a second gas introducing portion (lower gas introducing portion). The lower shower plate 150 is formed so as to have such a size as covers the substrate to be processed 100 supported on the substrate support table 104. The lower shower plate 150 is formed into a flat-box shape having a pair of plate materials 151a, 151b facing each other in such a manner that the second gas is allowed to flow in an internal space S3. The internal space S3 of the lower shower plate 150 is opened to the outside of the vacuum vessel 102 via an opening 152 made in the sidewall 102c of the vacuum vessel 102. The second gas is introduced into the internal space S3 of the lower shower plate 150 via the opening 152.

In the lower plate material 151b of the lower shower plate 150, a large number of gas injection holes 153 are made. In the lower shower plate 150, the aperture ratio per unit area of the gas injection holes 153 is set so that the conductance (the reciprocal of physical resistance) of the gas injection holes 153 to the gas flow in the upstream of the gas flow in the lower shower plate 150 may be smaller and the conductance of the gas injection holes 153 to the gas flow in the downstream of the gas flow in the lower shower plate 150 may be larger. Specifically, the aperture ratio per unit area of the gas injection holes 153 is set so that the conductance may be smaller in the upstream of the gas flow in the lower shower plate 150 and be larger in the downstream of the gas flow. This enables the second gas to be injected uniformly into the vacuum vessel 102. Although not shown, the lower shower plate 150 has a large number of through-holes in it to allow the first gas and oxygen radicals to flow between the top region of the lower shower plate 150 and the bottom region of the lower shower plate 150.

It is desirable that the lower gas supply system 107 should be kept at a temperature in the range of about 80° C. to 200° C. To achieve this, the lower gas supply system 107 may be provided with the heating means 111 included in the insulating film forming apparatus 1 of the third embodiment or the heating means 111 included in the insulating film forming apparatus 1 of the fourth embodiment.

As described above, use of the insulating film forming apparatus 1 of this embodiment makes it possible to supply the second gas from above the substrate 100 into the vacuum vessel 102 uniformly. Therefore, when an insulating film 101 is formed on the substrate to be processed 100, good film-thickness controllability and film-thickness uniformity can be realized.

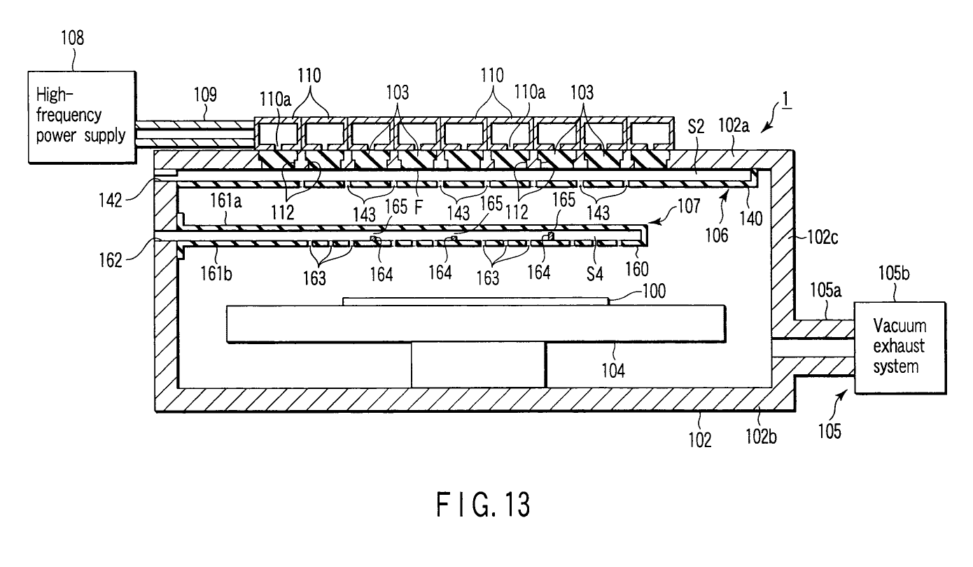

Hereinafter, referring to FIG. 13, an insulating film forming apparatus according to a sixth embodiment of the present invention will be explained.

The insulating film forming apparatus of the sixth embodiment differs from the insulating film forming apparatus 1 of the third embodiment in the upper gas supply system 106 and lower gas supply system 107. Since the remaining configuration is the same as that of the third embodiment, the same parts are indicated by the same reference numerals and repetitive explanation will be omitted.

The upper gas supply system 106 is the same as the upper gas supply system 106 included in the insulating film forming apparatus 1 explained in the third embodiment.

The lower gas supply system 107 has a lower shower plate 160 as a lower gas introducing portion. The lower shower plate 160 is formed so as to have such a size as covers the substrate to be processed 100 supported on the substrate support table 104. The lower shower plate 160 is formed into a flat-box shape having a pair of plate materials 161a, 161b facing each other in such a manner that the second gas is allowed to flow in an internal space S4. The internal space S4 of the lower shower plate 160 is opened to the outside of the vacuum vessel 102 via an opening 162 made in the sidewall 102c of the vacuum vessel 102. The second gas is introduced into the internal space S4 of the lower shower plate 160 via the opening 162.

In the internal space S4 of the lower shower plate 160, a plurality of partition walls 164 to adjust the flow of the second gas are provided. The size of the partition walls is set so that the conductance of the partition walls 164 to the gas flow may be larger in the upstream of the gas flow in the lower shower plate 160 and the conductance of the partition walls 164 to the gas flow may be smaller in the downstream of the gas flow in the lower shower plate 160. Specifically, the height of each partition wall 164 is set so as to be smaller in the upstream of the gas flow in the lower shower plate 160 and be larger in the downstream of the gas flow. Making the partition walls 164 in the upstream of the gas flow with a high inflow pressure of the second gas smaller enables the conductance in the upstream of the gas flow to be made larger. Making the partition walls 164 in the downstream of the gas flow with a low inflow pressure of the second gas larger enables the conductance in the downstream of the gas flow to be made smaller.

In the lower plate material 161a of the lower shower plate 160, a large number of gas injection holes 163 are provided for the regions divided by the partition walls 164 in a one-to-one correspondence. This causes the second gas to be divided into the flow passing through clearances 165 limited by the partition walls 164 and the flow injecting from the gas injection holes 163. Changing the conductance by the partition walls 164 makes it possible to adjust the flow rate ratio of the flow through the clearances 165 to the flow injecting from the gas injection holes 163. Adjusting the flow rate ratio to a desired value enables the second gas to be injected from the region corresponding to almost the whole region of the undersurface of the lower shower plate 160 into the vacuum vessel 102 uniformly. Although not shown, the lower shower plate 160 has a large number of through-holes in it to allow the first gas and oxygen radicals to flow between the top region of the lower shower plate 160 and the bottom region of the lower shower plate 160.

It is desirable that the lower gas supply system 107 should be kept at a temperature in the range of about 80° C. to 200° C. To achieve this, the lower gas supply system 107 may be provided with the heating means 111 included in the insulating film forming apparatus 1 of the third embodiment or the heating means 111 included in the insulating film forming apparatus 1 of the fourth embodiment.

As described above, use of the insulating film forming apparatus 1 of this embodiment makes it possible to supply the second gas from above the substrate 100 into the vacuum vessel 102 uniformly. Therefore, when an insulating film 101 is formed on the substrate to be processed 100, good film-thickness controllability and film-thickness uniformity can be realized.

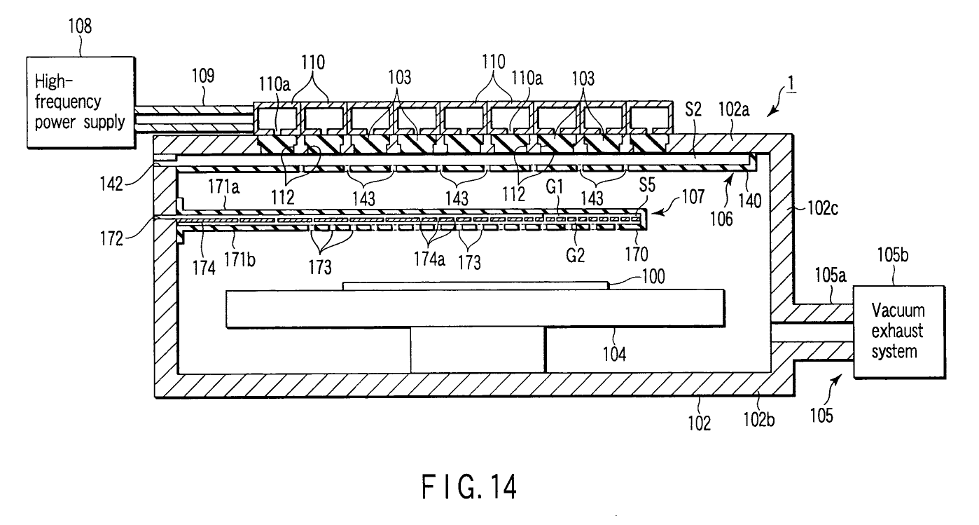

Hereinafter, referring to FIG. 14, an insulating film forming apparatus according to a seventh embodiment of the present invention will be explained.

The insulating film forming apparatus of the seventh embodiment differs from the insulating film forming apparatus 1 of the third embodiment in the upper gas supply system 106 and lower gas supply system 107. Since the remaining configuration is the same as that of the third embodiment, the same parts are indicated by the same reference numerals and repetitive explanation will be omitted.

The upper gas supply system 106 is the same as the upper gas supply system 106 included in the insulating film forming apparatus 1 explained in the fifth embodiment.

The lower gas supply system 107 has a lower shower plate 170 as a second gas introducing portion (lower gas introducing portion). The lower shower plate 170 is formed so as to have such a size as covers the substrate to be processed 100 supported on the substrate support table 104. The lower shower plate 170 is formed into a flat-box shape having a pair of plate materials 171a, 171b facing each other. Between the plate materials 171a, 171b, a diffuser plate 174 having a plurality of openings 174a in it is provided. The diffuser plate 174 divides an internal space S5 in the lower shower plate 170 into an upper gas chamber G1 as a first gas chamber and a lower gas chamber G2 as a second gas chamber. In the internal space S5 of the lower shower plate 170, the upper gas chamber G1 is opened to the outside of the vacuum vessel 102 via an opening 172 made in the sidewall 102c of the vacuum vessel 102. From the opening 162, the second gas is introduced into the upper gas chamber G1 of the lower shower plate 170. In the lower plate material 171b of the shower plate 170, a plurality of gas injection holes 173 are made.

In the lower shower plate 170, the gas flow between the upper gas chamber G1 and lower gas chamber G2 is adjusted according to the size, number, shape, or the like of the openings 174a in the diffuser plate 174. In this embodiment, the aperture ratio per unit area of the openings 174a in the diffuser plate 174 is set so that the conductance of the openings 174a to the gas flow in the upstream of the gas flow in the lower shower plate 170 may be smaller and the conductance of the openings 174a to the gas flow in the downstream of the gas flow in the lower shower plate 170 may be larger. Specifically, the aperture area per unit area of the diffuser plate 174 is set smaller in the upstream of the gas flow with a high inflow pressure of the second gas, thereby making the conductance smaller. The aperture area per unit area of the diffuser plate 174 is set larger in the downstream of the gas flow with a low inflow pressure of the second gas, thereby making the conductance larger. This enables the second gas to be sent uniformly to the lower gas chamber G2 from the region corresponding to almost the whole area of the undersurface of the diffuser plate 174. As a result, the second gas is sent uniformly into the vacuum vessel 102 from the region corresponding to almost the whole area of the undersurface of the lower shower plate 157.

It is desirable that the lower gas supply system 107 should be kept at a temperature in the range of about 80° C. to 200° C. To achieve this, the lower gas supply system 107 may be provided with the heating means 111 included in the insulating film forming apparatus 1 of the third embodiment or the heating means 111 included in the insulating film forming apparatus 1 of the fourth embodiment.

As described above, use of the insulating film forming apparatus 1 of this embodiment makes it possible to supply the second gas from above the substrate 100 into the vacuum vessel 102 uniformly. Therefore, when an insulating film 101 is formed on the substrate to be processed 100, good film-thickness controllability and film-thickness uniformity can be realized.

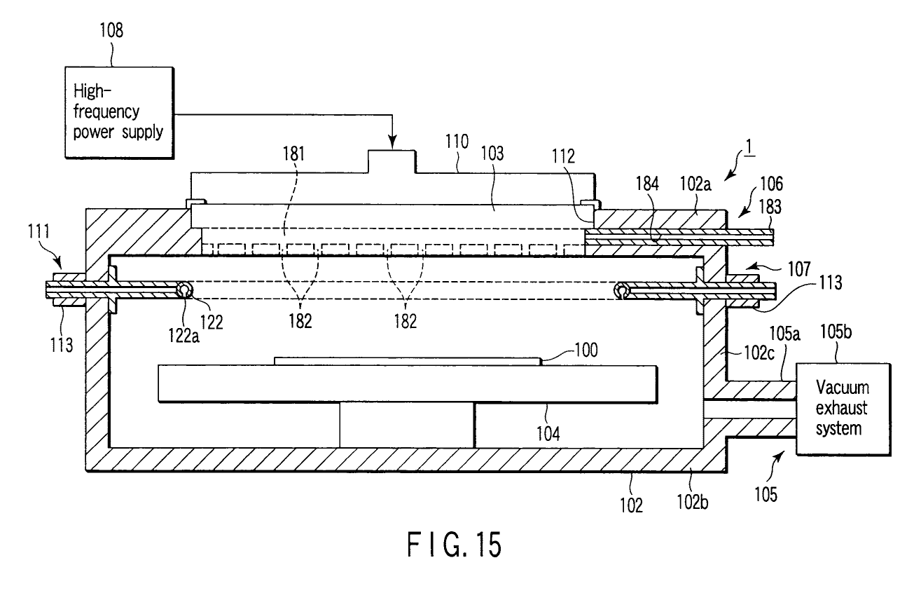

Hereinafter, referring to FIG. 15, an insulating film forming apparatus according to an eighth embodiment of the present invention will be explained.

The insulating film forming apparatus 1 of the eighth embodiment differs from the insulating film forming apparatus 1 of the third embodiment in the upper gas supply system 106. Since the remaining configuration is the same as that of the third embodiment, the same parts are indicated by the same reference numerals and repetitive explanation will be omitted.

The upper gas supply system 106 of the eighth embodiment is formed integrally with the dielectric windows 103. Specifically, in the dielectric windows 103, there are provided a gas flow path 181 which allows the first gas to flow, a plurality of connecting paths 182 which connect the gas flow path 181 to the inside of the vacuum vessel 102, and a connecting tube 183 which connects the gas flow path 181 to the outside of the vacuum vessel 102. The gas flow path 181 and the connecting paths 182 are formed by cutting the dielectric windows 103. The connecting tube 183 is connected to the gas flow path 181. The gas flow path 181 and connecting tube 183 constitute a first gas introducing portion (upper gas introducing portion). The opening end of the connecting path 182 makes a gas injection hole for introducing the first gas into the vacuum vessel 102.

The connecting tube 183 is laid in a through-hole 184 made in the top wall 102 of the vacuum vessel 102 and extends outside the vacuum vessel 102. The connecting tube 183 may be integral with or separate from the dielectric windows 103. In this case, too, the inside face of each dielectric window 103 functions as an electromagnetic wave incident face F. Since the remaining configuration is the same as that of the insulating film forming apparatus 1 of the third embodiment, the same parts are indicated by the same reference numeral and repetitive explanation will be omitted.

The insulating film forming apparatus 1 of the eighth embodiment enables the first gas supplied from the first gas supply system to be decomposed efficiently near the dielectric member 103 and therefore oxygen radicals to be produced efficiently.

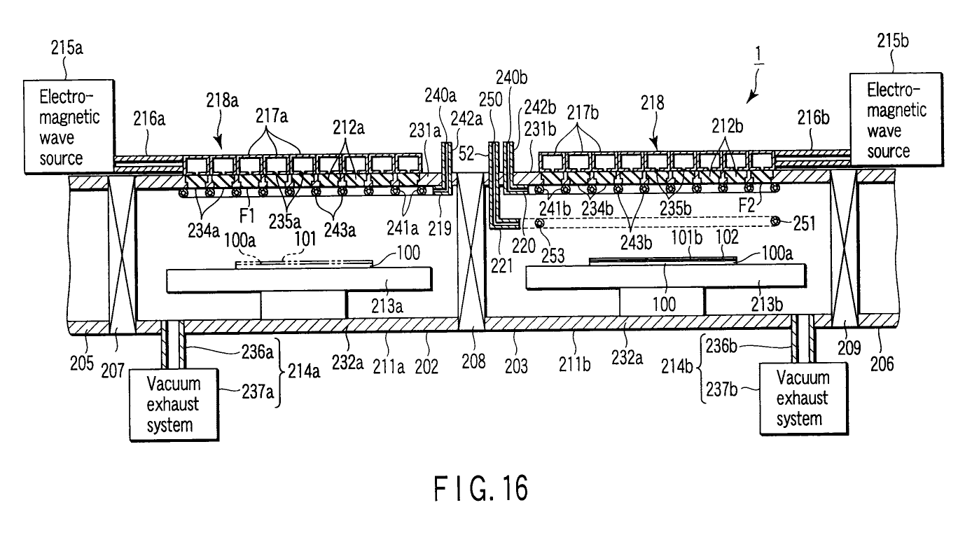

Hereinafter, a ninth embodiment of the present invention will be explained. FIG. 16 shows a plasma processing apparatus (insulating film forming apparatus) used suitably in executing an insulating film forming method according to the ninth embodiment.

The insulating film forming apparatus 1 comprises, for example, a first processing chamber 202, a second processing chamber 203, a load chamber 205, an unload chamber 206, a first, a second, and a third gate valve 207, 208, 209 serving as a first, a second, and a third connecting mechanism, and a substrate moving mechanism (not shown).

The first processing chamber 202 includes a vacuum vessel 211a as a processing vessel, one or more (e.g., nine) dielectric members 212a, a substrate support table 213a, an electromagnetic wave source 215a, a waveguide 216a, an antenna 218a, a gas exhaust system 214a, and a first gas supply system 219. The second processing chamber 203 includes a vacuum vessel 211b as a processing vessel, one or more (e.g., nine) dielectric members 212b, a substrate support table 213b, an electromagnetic wave source 215b, a waveguide 216b, an antenna 218b, a gas exhaust system 214b, a second gas supply system 220, and a third gas supply system 221. In the ninth embodiment, the vacuum vessel 211a, dielectric members 212a, substrate support table 213a, gas exhaust system 214a, electromagnetic wave source 215a, waveguide 216a, and antenna 218a included in the first processing chamber 202 are the same in configuration as the vacuum vessel 211b, dielectric members 212b, substrate support table 213b, gas exhaust system 214b, electromagnetic wave source 215b, waveguide 216b, and antenna 218b included in the second processing chamber 203, respectively.

The vacuum vessels 211a, 221b are formed so as to have such strength as enables its inside to be depressurized to a vacuum or to its vicinity. Metal material, such as aluminum, may be used as a material for the vacuum vessels 211a, 211b. In the top walls 231a, 231b of the vacuum vessels 211a, 211b, the dielectric members 212a, 212b are provided so as to constitute a part of the walls of the vacuum vessels 211a, 211b. These dielectric members 212a, 212b are also formed so as to have such strength as enables the inside of the vacuum vessels 211a, 211b to be depressurized to a vacuum or to its vicinity. Dielectric material, such as synthetic quartz, may be used as a material for the dielectric members 212a, 212b.

Specifically, the top walls 231a, 231b of the vacuum vessels 211a, 211b have one or more (e.g., nine) openings 234a, 234b in them. Each of the openings 234a, 234b forms a long, narrow space whose cross section is shaped almost like a T. The openings 234a, 234b are provided in parallel at specific intervals.

The dielectric members 212a, 212b are provided for the openings 234a, 234b in a one-to-one correspondence. Specifically, the dielectric members 212a, 212b are formed into long, narrow members whose cross section is shaped almost like a T so as to engage with the openings 234a, 234b respectively. The dielectric members 212a, 212b are engaged with the openings 234a, 234b, thereby sealing the openings 234a, 234b hermetically. As a result, in the top walls 231a, 231b, the nine dielectric members 212a, 212b are provided side by side so as to constitute a part of the walls of the vacuum vessels 211a, 211b. At this time, the top walls 231a, 231b not only are a part of the walls of the vacuum vessels 211a, 211b but also function as beams which support the dielectric members 212a, 212b. Hereinafter, the dielectric members 212a, 212b are referred to as the dielectric windows.

Although not shown, the vacuum vessels 211a, 211b have sealing mechanisms which seal the spacing between the top walls 231a, 231b and the dielectric windows 212a, 212b. Each of the sealing mechanisms has, for example, a groove made in the wall defining the openings 234a or 234b along its circumference and an O-ring inserted in the groove. The sealing mechanisms seal the spacing between the walls defining the openings 234a, 234b and the dielectric windows 212a, 212b, respectively. Inside the vacuum vessels 211a, 211b, the substrate support tables 213a, 213b are provided which support a substrate to be processed 100.

As the electromagnetic wave sources 215a, 215b, for example, a 2.45-GHz electromagnetic wave source may be used. The antennas 218a, 218b have nine waveguide slot antennas 217a, 217b, respectively. The waveguide slot antennas 217a, 217b, which have slit-like slots 235a, 235b in parts of the guide walls, radiate electromagnetic waves by electromagnetic coupling occurring near the slots 235a, 235b. Practically, the slots 235a, 235b function as antennas. The waveguide slot antennas 217a, 217b are provided for the dielectric windows 212a, 212b in a one-to-one correspondence. Specifically, the waveguide slot antennas 217a, 217b are arranged side by side so as to face the outside faces of the corresponding dielectric windows 212a, 212b.

The adjacent waveguide slot antennas 217a are connected to one another. Of these waveguide slot antennas 217a, the one closest to the electromagnetic wave source 215a is connected to the electromagnetic wave source 215a via the waveguide 216a. Similarly, the adjacent waveguide slot antennas 217b are connected to one another. Of these waveguide slot antennas 217b, the one closest to the electromagnetic wave source 215b is connected to the electromagnetic wave source 215b via the waveguide 216b.

As a result, the electromagnetic waves generated at the electromagnetic wave sources 215a, 215b are directed via the waveguides 216a, 216b to the corresponding waveguide slot antennas 217a, 217b.

The electromagnetic waves directed to the waveguide slot antennas 217a, 217b are radiated from the slots 235a, 235b and enter the vacuum chambers 211a, 211b via the dielectric windows 212a, 212b. Accordingly, in both of the first and second processing chambers 202, 203, the inside faces of the dielectric windows 212a, 212b make electromagnetic wave incident faces F1, F2, respectively.

Generally, since the waveguide slot antennas are made of meal, they have lower dielectric loss than antennas made of dielectric and features high resistance to a large amount of power. Moreover, since the waveguide slot antennas have a simple structure and therefore their radiation characteristic can be designed relatively accurately, they are suitable for a large-substrate insulating film forming apparatus. The insulating film forming apparatus of the embodiment where a plurality of waveguide slot antennas are arranged side by side are particularly suitable for a case where an insulating film is formed on a square substrate with a large area used for, for example, a large square liquid-crystal device. The antennas are not restricted to the waveguide slot antennas, as long as they are capable of radiating electromagnetic waves toward the vacuum vessels.

The gas exhaust systems 214a, 214b have gas exhaust sections 236a, 236b provided in the vacuum vessels 211a, 211b so as to connect to the inside of the vacuum vessels 211a, 211b, and vacuum exhaust systems 237a, 237b. The vacuum exhaust systems 237a, 237b may use, for example, turbo-molecular pumps. The vacuum vessels 211a, 211b can be exhausted to a specific degree of vacuum by operating the vacuum exhaust systems 237a, 237b.

The first gas supply system 219 included in the first processing chamber 202 is for introducing a processing gas as a first gas into the vacuum vessel 211a. The second gas supply system 220 included in the second processing chamber 203 is for introducing a processing gas into the vacuum vessel 211b. The first gas supply system 219 and second gas supply system 220 may have the same configuration.

The first gas supply system 219 has, for example, a first gas introducing pipe 240a. Similarly, the second gas supply system 220 has, for example, a second gas introducing pipe 240b. The first and second gas introducing pipes 240a, 240b are made of metal, such as aluminum, stainless steel, or titanium, or dielectric, such as silicon oxide, aluminum oxide, or aluminum nitride. When the effect of the first and second gas introducing pipes 240a, 240b on electromagnetic fields and plasma is taken into consideration, it is desirable that the first and second gas introducing pipes should be made of dielectric material. However, taking the process of forming tubes into account, it is inexpensive and easy to make the first and second gas introducing pipes 240a, 240b of metal material. Therefore, when the first and second gas introducing pipes 240a, 240b are made of metal material, an insulating film should be formed on the outside faces of the first and second gas introducing pipes 240a, 240b.

The first and second gas introducing pipes 240a, 240b are provided along the inside faces of the top walls (beams) 231a, 231b of the vacuum vessels 211a, 211b, keeping away from the regions where the dielectric windows 212a, 212b are formed. Specifically, the first gas introducing pipe 240a has a plurality of pipe sections 241a and an extended section 242a. The second gas introducing pipe 240b has a plurality of pipe sections 241b and an extended section 242b. The plurality of pipe sections 241a, 241b are laid in parallel with one another so as to run along the inside faces of the top walls (beams) 231a, 231b of the vacuum vessels 211a, 211b. In the underside (the substrate side) of the pipe section 241a, a plurality of gas injection holes 243a are provided at almost regular intervals in the longitudinal direction. In the underside (the substrate side) of the pipe section 241b, a plurality of gas injection holes 243b are provided at almost regular intervals in the longitudinal direction. The extended section 242a is laid so as to be at right angles with the pipe sections 241a pipes and connects these pipe sections 241a to one another. Similarly, the extended section 242b is laid so as to be at right angles with the pipe sections 241b pipes and connects these pipe sections 241b to one another. One end of the extended section 242a extends outside the vacuum vessel 211a via the top wall 231a of the vacuum vessel 211a. One end of the extended section 242b extends outside the vacuum vessel 211b via the top wall 231b of the vacuum vessel 211b. To one end of the extended section 242a, a processing gas cylinder (not shown) in which the processing gas is held can be provided detachably. Similarly, to one end of the extended section 242b, a processing gas cylinder (not shown) in which the processing gas is held can be provided detachably.

The gas injection holes 243b in the pipe section 221b of the second gas introducing pipe 240b are provided in positions whose distance from the electromagnetic wave incident face F2 is smaller than the skin depth δ of surface-wave plasma. In this embodiment, the second gas introducing pipe 240b is so formed that the distance between the virtual plane in which the gas injection holes 243b are made and the electromagnetic wave incident face F2 is less than 10 mm, for example, 3 mm. Laying the second gas introducing pipe 240b causes the gas injection holes 243b to be provided 3 mm below the electromagnetic wave incident face F.

The third gas supply system 221 included in the second processing chamber 203 is for introducing an insulating film forming gas as a second gas into the vacuum vessel 211b. The third gas supply system 221 is provided closer to the substrate support table 213b than the second gas supply system 220. The third gas supply system 221 has, for example, a third gas introducing pipe 250.

The third gas introducing pipe 250 is made of metal, such as aluminum, stainless steel, or titanium, or dielectric, such as silicon oxide, aluminum oxide, or aluminum nitride. In a transient state during the time elapsed until plasma at the beginning of discharge reaches a surface-wave plasma state, electromagnetic waves may reach the third gas supply system 221. Therefore, if the third gas introducing pipe 250 is made of metal material, the third gas introducing pipe 250 might have an effect on electromagnetic fields and plasma in the transient state. For this reason, when the effect of the third gas introducing pipe 250 on electromagnetic waves and plasma is considered, it is desirable that the third gas introducing pipe 250 should be made of dielectric material. When the third gas introducing pipe is made of metal material, it is desirable that an insulating film should be formed on the third gas introducing pipe 250.

The third gas introducing pipe 250 has, for example, a ring-shaped section 251 and an extended section 252. The ring-shaped section 251 is formed so as to be slightly larger than the outer edge of the substrate to be processed 100. In the ring-shaped section 251, a plurality of gas injection holes 253 are made in its underside (on the substrate side) along its periphery at almost regular intervals. One end of the extended section 252 is connected to the ring-shaped section 251. The other end of the extended section 252 extends outside the vacuum vessel 211b via the top wall 231b of the vacuum vessel 211b. An insulating film forming gas cylinder (not shown) in which an insulating film forming gas is held can be provided detachably to the other end of the extended section 252.

The gas injection holes 253 made in the ring-shaped section 251 are provided in positions whose distance from the electromagnetic wave incident face F2 is larger than the skin depth δ of surface-wave plasma. In this embodiment, the third gas introducing pipe 250 is so formed that the distance L2 between the virtual plane in which the gas injection holes 253 are made and the electromagnetic wave incident face F2 is 10 mm or more, for example, 30 mm. Laying the third gas introducing pipe 250 causes the gas injection holes 253 to be provided 30 mm below the electromagnetic wave incident face F2.

As the insulating film forming gas, gas including an organic silicon compound or an organic metallic compound may be used as described later. Since the organic silicon compound gas or organic metallic compound gas has a higher boiling point than silane, it is liable to liquefy. Therefore, when gas including an organic silicon compound or an organic metallic compound is used as the insulating film forming gas, to introduce the gas into the vacuum vessel stably, it is desirable that the third gas supply system should be kept at suitable temperature, that is, a temperature in the range of about 80° C. to 200° C. For this reason, the third gas supply system may be provided with heating means. The inside of the load chamber 205 is connected to the inside of the vacuum vessel 211a of the first processing chamber 202 via a first gate valve 207 in such a manner that they can be gated freely. The inside of the vacuum vessel 211a of the first processing chamber 202 is connected to the inside of the vacuum vessel 211b of the second processing chamber 203 via a second gate valve 208 in such a manner that they can be gated freely. The unload chamber 206 is connected to the inside of the vacuum vessel 211b of the second processing chamber 203 via a third gate valve 209 in such a manner that they can be gated freely.

The substrate moving mechanism is for moving (loading in and out) the substrate to be processed 100. Specifically, with the substrate moving mechanism, the substrate 100 is loaded in from the load chamber 205 to the first processing chamber 202, is transported from the first processing chamber 202 to the second processing chamber 203, and is loaded out from the second processing chamber 203 to the unload chamber 206.

The inside of the vacuum vessel 211a of the first processing chamber 202 may be connected to the inside of the vacuum vessel 211b of the second processing chamber 203 via a transfer chamber. While in this insulating film forming apparatus 1, the load chamber 205, first processing chamber 202, second processing chamber 203, and unload chamber 206 are connected in a line, the connection arrangement of the load chamber 205, first processing chamber 202, second processing chamber 203, and unload chamber 206 is not limited to this.

Next, an insulating film forming method will be explained. The formation of an insulating film proceeds in this order: the loading in of a substrate to be processed 100 to the first processing chamber 202 (oxidation chamber), oxidation process, the transport of the substrate 100 from the first processing chamber 202 to the second processing chamber 203 (film formation chamber), film forming process, and the loading out of the substrate 100 from the second processing chamber 203. In this embodiment, for example, a silicon wafer is used as a substrate to be processed 100.

Inside the load chamber 205, the substrate to be processed 100 is placed, with the surface to be processed 100a upward. The substrate 100 is loaded in from the load chamber 205 to the first chamber 202. The loading in of the substrate 100 takes about 20 seconds as a result of the opening and closing of the gate valve 207, the transport of the substrate 100, and the like.

The gas exhaust system 214a of the first processing chamber 102 is operated, thereby exhausting air from the vacuum vessel 211a. Thereafter, the processing gas is supplied to the vacuum vessel 211a via the first gas supply system 219. As the processing gas, for example, oxygen gas or a mixed gas of oxygen and rare gas including at least one of helium, neon, argon, krypton, and xenon is used. Helium gas, neon gas, argon gas, krypton gas, or xenon gas can be added to oxygen gas at an additive rate in the range of 10% to 99%. According to the additive rate, the oxidation speed of the substrate 100 can be increased. In this embodiment, the processing gas, a mixed gas of krypton gas and oxygen gas, is supplied to the vacuum vessel 211a in such manner that krypton gas flows at 388 SCCM, oxygen gas flows at 12 SCCM, and the total pressure is 80 Pa. It takes about 60 seconds for the gas pressure to become stable.

After the gas pressure in the vacuum vessel 211a has reached a specific gas pressure, the radiation of the electromagnetic wave is started. The electromagnetic wave is generated at the electromagnetic wave source 215a and is sent to each waveguide slot antenna 217a via the waveguide 216a. The electromagnetic wave sent to each waveguide slot antenna 217a is radiated from the slot (slit-like opening) 235a in the waveguide slot antenna 217a toward the inside of the vacuum vessel 211a. The electromagnetic wave radiated toward the vacuum vessel 211a passes through the dielectric windows 212a and enters the vacuum vessel 211a.

The electromagnetic wave which has entered the vacuum vessel 211a excites the processing gas. When the electron density in the plasma near the electromagnetic wave incident face (undersurface) F1 of the dielectric windows 212a has increased to some extent, the electromagnetic wave introduced into the vacuum vessel 211a via the dielectric windows 212a cannot propagate in the plasma, with the result that the electromagnetic wave attenuates. Accordingly, the electromagnetic wave does not reach a region separate from the electromagnetic wave incident face F1 of the dielectric windows 212a. As a result, surface-wave plasma appears near the electromagnetic wave incident face F1 of the vacuum vessel 211a.

In the state where surface-wave plasma is being produced, a high electron density has been achieved near the dielectric windows 212a, with the result that high-density oxygen atom active species are produced. The high-density oxygen atom active species diffuse as far as the substrate 100, oxidizing the substrate 100 efficiently. As a result, a first insulating film 101 is formed on the surface to be processed 100a, or the top surface of the substrate 100. In the state where surface-wave plasma is being produced, since the electron temperature near the surface of the substrate 100 is low (the electron energy is low), the sheath electric field near the surface of the substrate 100 is also weak. This reduces the incident energy of ions to the substrate 100, which suppresses ion damage to the substrate 100 in the process of oxidizing the substrate to be processed 100. In this embodiment, with a power density of 3 W/cm² and a processing time of 163 seconds, an oxide film (first insulating film 101) of about 3 nm in film thickness was obtained.

The gate valve 208 is opened and the substrate 100 oxidized in the first processing chamber 202 is transported to the second processing chamber 203. The transport of the substrate 100 takes about 40 seconds as a result of the opening and closing of the gate valve 208, the moving of the substrate 100, and the like. It is desirable that the moving of the substrate 100 from the first processing chamber 202 to the second processing chamber 203 should be done under vacuum. That is, it is desirable that the substrate should be moved, while the vacuum vessels 211a and 211b are evacuated. Moving the substrate 100 from the first processing chamber 202 to the second processing chamber 203 under vacuum this way suppresses the contamination of the interface between the first insulating film (oxide film) 100 formed by oxidation and the second insulating film (oxide film) 102 thereafter formed by CVD, which increases the reliability of the interface between the first insulating film 101 and the second insulating film 102.

Not only is the processing gas introduced via the second gas supply system 202 into the vacuum vessel 211b of the second processing chamber 203, but the second gas is introduced vie the third gas supply system 221 into the vacuum vessel 211b. As the processing gas, for example, oxygen gas or a mixed gas of oxygen and rare gas including at least one of helium, neon, argon, krypton, and xenon is used.

As the insulating film forming gas, for example, gas including silane, an organic silicon compound (such as tetra-alkoxy silane, vinyl alkoxy silane, alkyl tri-alkoxy silane, phenyl tri-alkoxy silane, polymethyl disiloxane, or polymethyl cyclo tetra-siloxane), or an organic metallic compound (such as tri-methyl aluminum, tri-ethyl aluminum, tetra-propoxy zirconium, penta-ethoxy tantalum, or tetra-propoxy hafnium) is used. In this embodiment, oxygen gas is used as the processing gas and tetra-ethoxy silane, a kind of tetra-alkoxy silane, is used as the insulating film forming gas. Oxygen gas is supplied as the processing gas to the vacuum vessel 211b at 400 SCCM and tetra-ethoxy silane is supplied as the insulating film forming gas to the vacuum vessel 211b at 10 SCCM until the total pressure reaches 80 Pa.

After the gas pressure in the vacuum vessel 211b has reached a specific gas pressure, the radiation of the electromagnetic wave is started. The electromagnetic wave is generated at the electromagnetic wave source 215b and is sent to each waveguide slot antenna 217b via the waveguide 216b. The electromagnetic wave sent to each waveguide slot antenna 217b is radiated from the slot (slit-like opening) 235b in the waveguide slot antenna 217b toward the inside of the vacuum vessel 211b. The electromagnetic wave radiated toward the vacuum vessel 211b passes through the dielectric windows 212b and enters the vacuum vessel 211b.

The electromagnetic wave which has entered the vacuum vessel 211b excites the processing gas. When the electron density in the plasma near the electromagnetic wave incident face (undersurface) F2 of the dielectric windows 212b has increased to some extent, the electromagnetic wave introduced into the vacuum vessel 211b via the dielectric windows 212b cannot propagate in the plasma, with the result that the electromagnetic wave attenuates. Accordingly, the electromagnetic wave does not reach a region separate from the electromagnetic wave incident face F2 of the dielectric windows 212b. As a result, surface-wave plasma appears near the electromagnetic wave incident face F2 of the vacuum vessel 211a. In the state where surface-wave plasma is being produced, the surface-wave plasma produces oxygen radicals as active species efficiently.

The produced oxygen radicals flow in diffusion flux form as far as the region into which the insulating film forming gas has been introduced and react with tetra-ethoxy silane. As a result, the decomposition of tetra-ethoxy silane is enhanced, causing silicon oxide to be deposited on the substrate to be processed 100. Consequently, a second insulating film (silicon oxide film formed by CVD techniques) 102 is formed on the first insulating film 101.

Since the insulating film forming gas is introduced closer to the substrate 100 than the processing gas, the electromagnetic wave is shielded by the high-density plasma and it is difficult for the electromagnetic wave to reach the region into which the insulating film forming gas has been introduced. Therefore, tetra-ethoxy silane is less liable to be decomposed excessively by the electromagnetic wave. In the state where surface-wave plasma is being produced, since the electron temperature near the surface of the substrate 100 is low (the electron energy is low), the sheath electric field near the surface of the substrate 100 is also weak. This reduces the incident energy of ions to the substrate 100, which suppresses ion damage to the substrate 100 and the first insulating film 101 in the process of forming the second insulating film 102. In this embodiment, with a power density of 3 W/cm², silicon oxide was deposited at a film forming speed of about 45 nm/min.

Furthermore, in a case where a mixed gas of krypton gas and oxygen gas was used as the processing gas, when krypton gas was supplied at 388 SCCM and oxygen gas was supplied at 12 SCCM to the vacuum vessel 211b to mix with each other and tetra-ethoxy silane, a kind of a kind of tetra-alkoxy silane, was supplied as the insulating film forming gas at 10 SCCM to the vacuum vessel 211b, silicon oxide was deposited at a film forming speed of about 45 nm/min and a total pressure of 80 Pa with a power density of 3 W/cm².

The substrate 100 is loaded out of the second processing chamber 3. The loading out of the substrate generally takes about 20 seconds as a result of the opening and closing of the gate valve 209, the transport of the substrate 100, and the like. Then, the formation of an insulating film on the substrate 100 is completed.

As described above, in the insulating film forming method of this embodiment, after the first insulating film 101 is formed by oxidizing the surface to be processed 100a of the substrate 100 using oxygen atom active species, the second insulting film 102 is formed on the first insulating film 101 by chemical vapor deposition using surface-wave plasma, thereby forming an insulating film on the substrate 100. Therefore, it is possible to form a high-quality insulating film on the substrate 100, while suppressing damage done to the substrate 100 and the insulating film (a stacked film of the first insulating film 101 and the second insulating film 102) formed on the substrate 100.

Hereinafter, a tenth embodiment of the present invention will be explained. FIG. 17 shows an insulating film forming apparatus suitably used in carrying out an insulating film forming method related to the tenth embodiment.

An insulating film forming apparatus 60 comprises, for example, a processing chamber 204, a load chamber 205, an unload chamber 206, a first and a second gate valve 210, 211 serving as a first and a second connecting mechanism, and a substrate moving mechanism (not shown).

The processing chamber 204 includes a vacuum vessel 261 as a processing vessel, one or more (e.g., nine) dielectric members 262, a substrate support table 263, a high-frequency power supply 265, a waveguide 266, an antenna 268, a gas exhaust system 264, a first gas supply system 269, and a second gas supply system 270. In this embodiment, since the vacuum vessel 261, dielectric members 262, substrate support table 263, gas exhaust system 264, high-frequency power supply 265, waveguide 266, and antenna 268 included in the processing chamber 204 are the same in configuration as the vacuum vessels 211a, 211b, dielectric members 211a, 211b, substrate support table 213a, 213b, gas exhaust systems 214a, 214b, electromagnetic wave sources 215a, 215b, waveguides 216a, 216b, and antennas 218a, 218b included in the insulating film forming apparatus 1 of the ninth embodiment, respectively, explanation of them will be omitted. Moreover, the first gas supply system 269 may have the same configuration as that of the first and second gas supply systems 219, 220 included in the insulating film forming apparatus 1 of the ninth embodiment, repetitive explanation will be omitted.

In FIG. 17, numeral 291 indicates a gas introducing pipe corresponding to the gas introducing pipe 240b, numeral 292 indicates a pipe section corresponding to the pipe section 241b, numeral 293 indicates an extended section corresponding to the extended section 242b, numeral 294 indicates a gas injection hole corresponding to the gas injection hole 243b, numeral 296 indicates an opening corresponding to the opening 234b, numeral 297 indicates a slot (antenna) corresponding to the slot 235b, numeral 298 indicates a gas exhaust section corresponding to the gas exhaust section 236b, numeral 299 indicates a vacuum exhaust system corresponding to the vacuum exhaust system 237b, and reference symbol F indicates an electromagnetic wave incident face.

The second gas supply system 270 is made of metal, such as aluminum, stainless steel, or titanium, or dielectric, such as silicon oxide, aluminum oxide, or aluminum nitride. It is desirable that the second gas supply system 270 should be made of dielectric material. The reason for this is the same as why it is desirable that the third gas supply system 221 included in the insulating film forming apparatus 1 of the ninth embodiment should be made of dielectric.

The second gas supply system 270 has a shower plate 280 as a gas introducing portion. The shower plate 280 is formed into a hollow shape and allows the processing gas to flow through the internal space S. One end 280a of the shower plate 280 extends outside the vacuum vessel 261 via the top wall 295 of the vacuum vessel 261. To one end 280a of the shower plate 280, an insulating film forming gas cylinder (not shown) in which the insulating film forming gas is held can be provided detachably. In the shower plate 280, a large number of flow holes 281 to allow the processing gas or oxygen radicals to flow are made. Moreover, in the wall of the shower plate 280, a large number of gas injection holes 282 are made. The insulating film forming gas introduced into the internal space S of the shower plate 280 is injected from the gas injection holes 282 into the vacuum vessel 261.

Next, an insulating film forming method will be explained. The formation of an insulating film proceeds in this order: the loading in of a substrate to be processed 100 to the vacuum vessel 261, oxidation process, film forming process, the loading out of the substrate 100 from the vacuum vessel 261, and the process of cleaning the inside of the vacuum vessel 261. In this embodiment, for example, a silicon wafer is used as a substrate to be processed 100.

Inside the load chamber 205, the substrate to be processed 100 is placed, with the surface to be processed 100a upward. The substrate 100 is loaded in from the load chamber 205 to the vacuum vessel 261 of the processing chamber 204. The loading in of the substrate 100 takes about 20 seconds as a result of the opening and closing of the gate valve 210, the transport of the substrate 100, and the like.

The gas exhaust system 264 is operated, thereby exhausting air from the vacuum vessel 261. Thereafter, the processing gas is supplied to the vacuum vessel 261 via the first gas supply system 269. As the processing gas, for example, oxygen gas or a mixed gas of oxygen and rare gas including at least one of helium, neon, argon, krypton, and xenon is used. Helium gas, neon gas, argon gas, krypton gas, or xenon gas can be added to oxygen gas at an additive rate in the range of 10% to 99%. According to the additive rate, the oxidation speed of the substrate 100 can be increased. In this embodiment, oxygen gas is used as the processing gas. Oxygen gas is supplied at 400 SCCM to the vacuum vessel 211a until the total pressure reaches 80 Pa. It takes about 60 seconds for the gas pressure to become stable.

After the gas pressure in the vacuum vessel 261 has reached a specific gas pressure, the radiation of the electromagnetic wave is started. The electromagnetic wave is generated at the high-frequency power supply 265 and is sent to each waveguide slot antenna 267 via the waveguide 266. The electromagnetic wave sent to each waveguide slot antenna 267 is radiated from the slot (slit-like opening) 297 in the waveguide slot antenna 267 toward the inside of the vacuum vessel 261. The electromagnetic wave radiated toward the vacuum vessel 261 passes through the dielectric windows 62 and enters the vacuum vessel 261.

The electromagnetic wave which has entered the vacuum vessel 261 excites the oxygen gas as the processing gas. When the electron density in the plasma near the electromagnetic wave incident face (undersurface) F of the dielectric windows 262 has increased to some extent, the electromagnetic wave introduced into the vacuum vessel 261 via the dielectric windows 262 cannot propagate in the plasma, with the result that the electromagnetic wave attenuates. Accordingly, the electromagnetic wave does not reach a region separate from the electromagnetic wave incident face F of the dielectric windows 262. As a result, surface-wave plasma appears near the electromagnetic wave incident face F of the vacuum vessel 261.

In the state where surface-wave plasma is being produced, a high electron density has been achieved near the dielectric windows 262, with the result that high-density oxygen atom active species are produced. The high-density oxygen atom active species diffuse as far as the substrate 100, oxidizing the substrate 100 efficiently. As a result, a first insulating film 101 is formed on the surface to be processed 100a, or the top surface of the substrate 100. In the state where surface-wave plasma is being produced, since the electron temperature near the surface of the substrate 100 is low (the electron energy is low), the sheath electric field near the surface of the substrate 100 is also weak. This reduces the incident energy of ions to the substrate 100, which suppresses ion damage to the substrate 100 in the process of oxidizing the substrate to be processed 100. In this embodiment, with a power density of 3 W/cm² and a processing time of 30 seconds, an oxide film (first insulating film 101) of about 2 nm in film thickness was obtained.

The supply of the processing gas is continued, causing the plasma used in the oxidation process to keep discharging. In this state, the insulating film forming gas is supplied from the second gas supply system 270 to the vacuum vessel 261. As the insulating film forming gas, for example, gas including silane, an organic silicon compound (such as tetra-alkoxy silane, vinyl alkoxy silane, alkyl tri-alkoxy silane, phenyl tri-alkoxy silane, polymethyl disiloxane, or polymethyl cyclo tetra-siloxane), or an organic metallic compound (such as tri-methyl aluminum, tri-ethyl aluminum, tetra-propoxy zirconium, penta-ethoxy tantalum, or tetra-propoxy hafnium) is used. In this embodiment, oxygen gas is still used as the processing gas and tetra-ethoxy silane, a kind of tetra-alkoxy silane, is used as the insulating film forming gas. Oxygen gas is supplied as the processing gas to the vacuum vessel 211b at 400 SCCM and tetra-ethoxy silane is supplied as the insulating film forming gas to the vacuum vessel 211b at 10 SCCM until the total pressure reaches 80 Pa.

Since the supply of the processing gas is continued, causing the plasma used in the oxidation process to keep discharging, oxygen radicals are produced efficiently from the beginning of the film forming process. The produced oxygen radicals flow in diffusion flux form as far as the region into which the insulating film forming gas has been introduced and react with tetra-ethoxy silane. As a result, the decomposition of tetra-ethoxy silane is enhanced, causing silicon oxide to be deposited on the substrate to be processed 100. Consequently, a second insulating film (silicon oxide film formed by CVD techniques) 102 is formed on the first insulating film 101.

Since the insulating film forming gas is introduced closer to the substrate 100 than the processing gas, the electromagnetic wave is shielded by the high-density plasma and it is difficult for the electromagnetic wave to reach the region into which the insulating film forming gas has been introduced. Therefore, tetra-ethoxy silane is less liable to be decomposed excessively by the electromagnetic wave. In the state where surface-wave plasma is being produced, since the electron temperature near the surface of the substrate 100 is low (the electron energy is low), the sheath electric field near the surface of the substrate 100 is also weak. This reduces the incident energy of ions to the substrate 100, which suppresses ion damage to the substrate 100 and the first insulating film 101 in the process of forming the second insulating film 102. In this embodiment, with a power density of 1.5 W/cm², silicon oxide was deposited at a film forming speed of about 27 nm/min.

When the plasma discharging is stopped temporarily after the completion of the oxidation process and then is resumed after the start of a film forming process (or after the start of the supply of the insulating film forming gas), the insulating film forming gas is decomposed insufficiently in the transient period immediately after the start of discharging, which might permit a poor-quality insulating film to be deposited on the first insulating film.

In contrast, as in this embodiment, when the film forming process is started after the oxidation process, keeping the plasma discharging, the film quality of the second insulating film 102 formed from the beginning of the film forming process can be made stable.

Since a fluctuation in the plasma state leads to a fluctuation in the film quality, it is desirable that the plasma state should be kept as stable as possible. Specifically, when the supply of the processing gas is stopped temporarily after the completion of the oxidation process and then is resumed after the start of the film forming process (or after the start of the supply of the insulating film forming gas), this causes the plasma state to fluctuate at the beginning of the film forming process.

In contrast, as in this embodiment, when the film forming process is started, keeping the supply of the processing gas, the plasma state can be made stable from the beginning of the film forming process, which enables the film quality of the second insulating film 102 formed to be stabilized.

Furthermore, to stabilize the plasma state from the beginning of the film forming process, the flow rate of the insulating film forming gas should be set smaller than that of the processing gas at the start of supply in the film forming process. Preferably, the flow rate of the insulating film forming gas is within 10% of the total flow rate. This enables a fluctuation in the plasma to be made smaller. When the flow rate of the second process gas is increased, it is desirable that the flow rate of the second process gas should be increased stepwise to prevent a rapid fluctuation in the plasma state.

After the film forming process is completed, the substrate 100 is loaded out of the vacuum vessel 261. The loading out of the substrate 100 generally takes about 20 seconds as a result of the opening and closing of the gate valve 211, the transport of the substrate 100, and the like.

After the substrate is loaded out of the vacuum vessel 261, the process of cleaning the inside of the vacuum vessel 261 is started. That is, the insulating film deposited to the inside of the vacuum vessel 261 in the film forming process is removed. As a result, even when insulating films are formed on the substrate 100 sequentially, the oxidation process of a subsequent substrate 100 can be carried out stably. The cleaning process can be performed by introducing etching gas, such as nitrogen trifluoride, from the first or second gas supply system 269, 270 and exciting it using electromagnetic waves. This completes the formation of an insulating film on the substrate 100.

In this embodiment, since the oxidation process and the film forming process are carried out sequentially in the same vacuum vessel 261, it is unnecessary to transport the substrate 100 in proceeding from the oxidation process to the film forming process. Therefore, the process time can be shortened by about 40 seconds each time one substrate is processed.

As described above, like the ninth embodiment, the insulating film forming method of the tenth embodiment makes it possible to form a high-quality insulating film on the substrate to be processed 100, while suppressing damage done to the substrate 100 and the insulating film (a stacked film of the first insulating film 101 and second insulating film 102) formed on the substrate 100.

Furthermore, in the insulating film forming method of the tenth embodiment, the step of forming the first insulating film 101 includes the step of not only providing the substrate 100 but also supplying the processing gas, producing oxygen atom active species by producing surface-wave plasma using the processing gas in the vacuum vessel 261, and forming the first insulating film 101 on the substrate 100 by oxidizing the surface to be processed 100a of the substrate 100 using the oxygen atom active species. Moreover, the step of forming the second insulating film 102 includes the step of, while not only supplying the processing gas to the vacuum vessel 261 continuously but also keeping surface-wave plasma discharging continuously, further supplying the insulating film forming gas to the vacuum vessel 261, and forming the second insulating film 102 on the first insulating film 101 by depositing oxide on the first insulating film 101 by CBD techniques using surface-wave plasma.

Therefore, it is possible not only to suppress damage done to and the contamination of the substrate 100 in the middle of processing and form a high-quality insulating film but also to shorten the process time.

The insulating film forming method, insulating film forming apparatus, and plasma film forming apparatus of the present invention are not limited to the above-described embodiment. This invention may be practiced or embodied in still other ways without departing from the spirit or essential character thereof.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-7. (canceled)

8. An insulating film forming method which forms an insulating film sequentially in a processing vessel by using an insulating film forming apparatus comprising:
a microwave source which generates a microwave;
a waveguide which transmits the microwave from the microwave source;
a plurality of waveguide slot antennas which are comprised of a plurality of openings provided on a sidewall of the waveguide and which irradiate the microwave from the plurality of openings;
a processing vessel including a dielectric window transmitting the microwave irradiated from the plurality of waveguide slot antennas as a part of a wall of an upper wall, and that enables a substrate to be processed to be provided on a bottom wall side therein;
a first gas supply system which is provided in the processing vessel so as to supply a first gas as a surface wave plasma producing gas in proximity of the microwave incident face for producing a high-density surface wave plasma, which has an increased electron density, only in the proximity of the microwave is incident, and which includes a first gas introducing portion that introduces a first gas including at least one of rare gas and oxygen gas into the processing vessel;
a second gas supply system which is provided in the processing vessel and in a position where a radical generated from the surface wave plasma is diffused, and which includes a second gas introducing portion that introduces a second gas including an organic silicon compound or an organic metallic compound into the processing vessel to cause the second gas to react chemically;
the insulating film forming method comprising:
forming a first insulating film comprised of an oxidation film, the first insulating film being formed by supplying a first gas including the oxygen gas into the processing vessel from the first gas supplying system in a state that supply of the second gas is stopped, and by oxidizing a surface to be processed of the substrate to be processed by oxygen atom active species produced by generating surface-wave plasma caused by the first gas; and
forming a second insulating film on the first insulating film by supplying a second gas including the organic metallic compound or organic silicon compound into the processing vessel from the second gas supplying system in a state that the surface-wave plasma is being generated, and by chemically reacting the second gas by oxygen atom active species produced from the surface-wave plasma.

9. The insulating film forming method according to claim 8, wherein the supplying the second gas into the processing vessel is performed in a state that the surface-wave plasma is being generated.

10. The insulating film forming method according to claim 8, wherein the first gas causes an oxygen gas to include at least one rare gas of helium, neon, argon, krypton, or xenon.
